(19) United States
(12) Patent Application Publication
(10) Pub. No.: US 2026/0286514 A1
(43) Pub. Date: Sep. 24, 2026

(54) SYSTEMS AND TECHNIQUES FOR SEMICONDUCTOR PROCESSING AND FORELINE CLEANING

(71) Applicant: Lam Research Corporation, Fremont, CA (US)

(72) Inventors: Curtis Warren Bailey, West Linn, OR (US); Erica Sakura Strandberg Pohl, Golden, CO (US); Todd Schroeder, Sherwood, OR (US); Troy Alan Gomm, Tigard, OR (US); Karl Frederick Leeser, West Linn, OR (US); Brian Lewis Ratliff, Hillsboro, OR (US); Aarsh Nilesh Dodhia, Sherwood, OR (US); Andrew Borth, Newberg, OR (US); Andrew H. Breninger, Newberg, OR (US); Dylan Windom, Aloha, OR (US); Chin-Jui Hsu, Portland, OR (US); Ragesh Puthenkovilakam, Portland, OR (US); Kurt Augustus Spies, Portland, OR (US)

(21) Appl. No.: 19/474,608

(22) PCT Filed: May 2, 2024
(86) PCT No.: PCT/US2024/027529

§ 371 Date: Oct. 10, 2025

Related U.S. Application Data
(60) Provisional application No. 63/499,936, filed on May 3, 2023.
(60) Provisional application No. 63/580,162, filed on Sep. 1, 2023.
(60) Provisional application No. 63/600,284, filed on Nov. 17, 2023.
(60) Provisional application No. 63/604,456, filed on Nov. 30, 2023.

(51) Int. Cl. C23C 16/44; C23C 16/52; H10P 72/00

(52) U.S. Cl. CPC C23C 16/4412; C23C 16/4405; C23C 16/52; H10P 72/0402

(57) ABSTRACT

A semiconductor processing system is provided. The system may have a processing chamber defining an interior volume, a foreline fluidically connected to the interior volume and configured to receive process gases from the interior volume, the foreline having a foreline network and a foreline outlet conduit downstream of the foreline network, a throttle valve in the foreline outlet conduit, having a movable gate with an orifice, and configured to control a flow of gases through the foreline, and a gas injector in the foreline network and configured to direct a ballast gas into a conduit of the foreline network. The system may have a remote plasma source interface fluidically connected to the foreline outlet conduit, downstream of the interior volume, and having a plasma passage configured to direct a remote plasma flow into the foreline outlet conduit.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Chemical deposition systems may be used to deposit films on substrates (e.g., semiconductor wafers, etc.). Examples of chemical deposition systems may include plasma-enhanced chemical vapor deposition (PECVD) systems, chemical vapor deposition (CVD) systems, and atomic layer deposition (ALD) systems. Such systems may include one or more showerheads that are positioned within a processing chamber having substrate processing regions. The substrate processing region may be defined between a bottom side of the showerhead and a wafer support (i.e., a pedestal, a substrate support, etc.) that may be positioned beneath each showerhead and configured to support a substrate within the substrate region. The bottom side of the showerhead may include ports facing the wafer support and configured to supply one or more precursor gases to facilitate deposition of layers of material onto the substrates. The chemical deposition systems may further include a foreline having various conduits, including a foreline network and a common foreline outlet conduit, fluidically connected with the processing chamber to evacuate process gases and materials from the processing chamber.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some embodiments, a semiconductor processing system may be provided. The system may have a processing chamber defining an interior volume, a foreline fluidically connected to the interior volume and configured to receive process gases from the interior volume, the foreline having a foreline network and a foreline outlet conduit downstream of the foreline network, a throttle valve in the foreline outlet conduit, having a movable gate with an orifice, and configured to control a flow of gases through the foreline, and a gas injector in the foreline network and configured to direct a ballast gas into a conduit of the foreline network.

In some embodiments, the gas injector may have an outlet positioned in the center of the conduit.

In some embodiments, the gas injector may have an outlet with a circular cross-sectional area.

In some embodiments, the conduit may have an internal bore diameter between about two times and about six times the diameter of the outlet.

In some embodiments, the gas injector may have an outlet with a pneumatic exhaust muffler.

In any of the above embodiments, the foreline network may have a first segment spanning between a first exhaust port of the processing chamber and a junction, a second segment spanning between a second exhaust port of the processing chamber and the junction, and a third segment spanning between, and fluidically interposed between, the junction and the foreline, and the conduit may be a part of the third segment such that the gas injector is positioned along the third segment and configured to direct the ballast gas flow into the third segment.

In any of the above embodiments, the system may further have a catcher in the foreline outlet conduit and downstream of the movable gate, and gas flowing through the foreline is configured to contact the catcher.

In some such embodiments, the catcher may have an accumulation surface configured to be impinged upon by the gas flowing through the foreline.

In some such embodiments, when the throttle valve is in a closed position, gas may be configured to flow through the orifice and into the catcher.

In some such embodiments, the catcher may further have an inlet configured to receive the gas and a plurality of outlets.

In any of the above embodiments, the throttle valve may be a pendulum valve.

In any of the above embodiments, a surface of the movable gate may have an aluminum.

In some embodiments, the movable gate comprises stainless steel and an aluminum coating.

In any of the above embodiments, the system may further have a remote plasma source interface (RPS interface) fluidically connected to the foreline outlet conduit, downstream of the interior volume, and having a plasma passage configured to direct a remote plasma flow into the foreline outlet conduit.

In some such embodiments, the RPS interface may be fluidically interposed between the foreline network and the throttle valve.

In some such embodiments, the plasma passage may be configured to direct the plasma flow along a direction having a component parallel to a center axis of the foreline outlet conduit.

In some such embodiments, the plasma passage may be configured to direct the plasma flow along a direction that is at between 30 degrees and 60 degrees relative to the center axis of the foreline outlet conduit.

In some such embodiments, the plasma passage may be configured to direct the plasma flow along a direction having a component perpendicular to a center axis of the foreline outlet conduit.

In some such embodiments, the RPS interface may further have a nozzle defining the plasma passage and extending into an interior of the foreline outlet conduit.

In some such embodiments, the plasma passage may have a first end portion and a second end portion configured to direct the plasma flow into the foreline outlet conduit, the first end portion may have a first diameter, and the second end portion may have a second diameter smaller than the first diameter.

In some such embodiments, the RPS interface may further have a nozzle defining the plasma passage and having one or more internal coolant channels configured to flow a coolant.

In some such embodiments, the RPS interface may further have a nozzle defining the plasma passage, and one or more heat sinks thermally coupled to an exterior surface of the nozzle and each having one or more coolant passages configured to flow a coolant.

In any of the above embodiments, the system may further have a ballast gas source fluidically connected to the gas injector; and one or more controllers having one or more processors and one or more memories that store instructions for controlling the system, the instructions are configured to cause the one or more processors to cause ballast gas to flow through the gas injector and into the foreline network during one or more processing operations.

In some such embodiments, the system may further have a pressure sensor configured to detect a pressure upstream of the gas injector, and the instructions may be further configured to cause the one or more processors to cause one controller to receive signals from the pressure sensor, and the ballast gas to flow, based on a detected pressure, through the gas injector and thereby maintain a portion of the foreline network within a pressure range.

In some such embodiments, one of the controllers is an upstream pressure controller.

In some such embodiments, the ballast gas may be flowed to maintain the portion of the foreline network within the pressure range using proportional-integral-derivative (PID) control.

In some such embodiments, the pressure sensor may be configured to measure the pressure in the interior volume.

In some such embodiments, the pressure range may be from about 7 Torr to about 11 Torr, from about 14 Torr to about 18 Torr, or from about 16 Torr to about 20 Torr.

In some such embodiments, the instructions may be further configured to cause the one or more processors to cause the throttle valve to be in a closed position while the ballast gas is flowed through the gas injector.

In some such embodiments, the one or more processing operations may be depositing one or more materials onto a substrate.

In some such embodiments, the instructions may be further configured to cause the one or more processors to cause the throttle valve to control the pressure within the interior volume during one or more other operations that are not the one or more processing operations.

In some such embodiments, one other operation may be a cleaning operation.

In some such embodiments, the system may further have a remote plasma source (RPS) configured to generate a remote plasma, and a remote plasma source interface (RPS interface) fluidically connected to the foreline and the RPS, downstream of the interior volume, and having a plasma passage configured to direct the remote plasma flow from the RPS into the foreline outlet conduit. The instructions may be further configured to cause the one or more processors to cause the RPS to generate the remote plasma, and the remote plasma to flow into the foreline outlet conduit during the cleaning operation.

In some such embodiments, the instructions may be further configured to cause the one or more processors to cause the ballast gas not to flow through the gas injector during the cleaning operation.

In some embodiments, a method may be provided. The method may include depositing one or more materials onto a substrate in a processing chamber, where the processing chamber defines an interior volume and is fluidically connected to a foreline, and where the foreline has a foreline network fluidically connected to the interior volume and is configured to receive process gases from the interior volume, maintaining, during the depositing, a throttle valve in a closed position, where the throttle valve has a movable gate with an orifice positioned in a foreline outlet conduit of the foreline and is configured to control gas flow through the foreline, and where the foreline outlet conduit is downstream of, and fluidically connected to, the foreline network and configured to fluidically connect with an exhaust system, and flowing, during the depositing, a ballast gas through a gas injector into a conduit of the foreline network.

In some embodiments, the flowing the ballast gas may include maintaining a pressure in a portion of the foreline network within a pressure range.

In some embodiments, the flowing the ballast gas may include controlling a pressure in the interior volume.

In some embodiments, the method may further include detecting a pressure upstream of the gas injector, wherein the flowing the ballast gas is based, at least in part, on the detected pressure.

In some such embodiments, the detecting the pressure may include detecting the pressure in the interior volume of the processing chamber.

In some embodiments, the method may further include performing one or more other operations that are not the depositing, and the one or more other operations are performed while the throttle valve is not in the closed position and the ballast gas is not flowing into the conduit.

In some such embodiments, the flowing the ballast gas may include maintaining a pressure in a portion of the foreline network within a pressure range, and during the one or more other operations, the foreline network may be at a second pressure range less than the pressure range.

In some such embodiments, one other operation may be a cleaning operation.

In some further such embodiments, the method may further include flowing, during the cleaning operation, a remote plasma from a remote plasma source (RPS) to a remote plasma source interface (RPS interface) fluidically connected to the foreline outlet conduit and the RPS, downstream of the interior volume, and having a plasma passage configured to direct the remote plasma flow from the RPS into the foreline outlet conduit.

Additional aspects will be set forth in the detailed description which follows, and, in part, will be apparent from the disclosure, or may be learned by practice of the disclosed embodiments and/or the claimed subject matter.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIG. 1A depicts a semiconductor processing system according to various implementations.

FIG. 1B depicts a magnified section of a portion of the system of FIG. 1A.

FIG. 1C depicts the semiconductor processing system 100 of FIG. 1A according to various implementations.

FIG. 2 depicts an enlarged cutaway view of an example portion of the semiconductor processing system of FIG. 1C, as taken from Region 1.

FIG. 3 depicts an enlarged cutaway view of Region 1 of the semiconductor processing system of FIG. 1C.

FIG. 4 depicts an enlarged cutaway view of an example portion of the semiconductor processing system of FIG. 1C, as taken from Region 2.

FIG. 5 depicts an enlarged view of the pendulum valve of FIG. 4.

FIG. 6 depicts an enlarged view of the pendulum valve of FIG. 5.

FIG. 7A depicts a schematic diagram of another example semiconductor processing system in one configuration.

FIG. 7B depicts the example semiconductor processing system of FIG. 7A in a second configuration.

FIG. 8A depicts a simplified magnified schematic of the system of FIG. 7A.

FIG. 8B depicts a simplified magnified schematic of the system of FIG. 7B.

FIG. 9 depicts a cross-sectional view of an example foreline anti-fouling assembly for foreline of FIG. 1C, as taken along a longitudinal axis of the catcher.

FIG. 10 depicts another implementation of the catcher of FIG. 9.

FIG. 11 depicts still another implementation of the catcher of FIG. 9.

FIG. 12 depicts a bottom perspective view of the panels of FIG. 11.

FIG. 13 depicts a side view of another implementation of the foreline anti-fouling assembly of FIG. 9.

FIG. 14 depicts a perspective end view of the catcher of FIG. 13.

FIG. 15 depicts an enlarged cutaway view of Region 1 of the semiconductor processing system of FIG. 1C.

FIG. 16 depicts a cross-sectional side view of a portion of the foreline with a gas injector.

FIG. 17 depicts a cross-sectional side view of a portion of the foreline with another gas injector.

FIG. 18 depicts one example technique according to various embodiments.

FIG. 19 depicts a cross-sectional view of a process tool, according to some implementations.

FIG. 20 depicts a cross-sectional view of a vacuum pumping system, according to some implementations.

FIG. 21 depicts a plan view of a foreline network, in accordance with some implementations.

FIG. 22 depicts a cross-sectional view of a process tool system.

FIG. 23 depicts a cross-sectional view of the process tool system of FIG. 22 undergoing a deposition operation.

FIG. 24 depicts a cross-sectional view of process tool system of FIG. 22 undergoing a cleaning operation.

FIG. 25 depicts a flow chart of a technique for performing a deposition operation in a vacuum process chamber according to some implementations.

FIG. 26 depicts a flow chart of a technique for performing a cleaning operation in a vacuum process chamber according to some implementations.

### DETAILED DESCRIPTION

Semiconductor processing tools have one or more processing chambers in which various processing operations are performed, such as deposition, etching, or both deposition and etching. Some processing chambers may be considered a single chamber such that they have a single station where only one substrate is processed at a time. Other processing chambers may be considered multi-station chambers such that they have two or more stations where two or more substrates can be processed at the same time. This can include two, three, four, five, six, or eight stations in a single chamber. During the processing operations in the processing chambers, deposition precursors, reactants, gases, contaminants, particulates, byproducts and the like flow through the processing chamber and may be exhausted from the processing chamber through a foreline to an exhaust system. The foreline may have a plurality of conduits or branches configured to flow gas from multiple exhaust ports of the processing chamber to a single outlet of the foreline. The plurality of conduits or branches may be referred to as a foreline network and the single outlet of the foreline may be referred to as the common foreline outlet conduit. The various foreline conduits in the foreline network may join to each other until they reach the single common foreline outlet conduit that is fluidically connected to the exhaust system.

Many tools use an adjustable valve downstream of the processing chamber as part of the foreline to facilitate regulation of chamber pressure at working levels while leaking process gas effluent into vacuum pumping system. In some instances, the adjustable valve may be opened slightly to create a small orifice through which effluent gases flow into foreline. A small valve opening may act as a flow restriction, enabling working pressures to exist in chamber upstream of the adjustable valve while permitting gases to exit chamber and flow into a large diameter conduit presented by the foreline downstream of the valve. As used herein, this adjustable valve may be referred to as a throttle valve.

As the deposition precursors, reactants, gases, contaminants, particulates, byproducts and the like exit the processing chamber and flow through the foreline network, unwanted deposition of such particulates and byproducts tends to occur within the foreline. This can include unwanted deposition on the conduits as well as flow control elements, like control valves, in the foreline. In some instances, the geometry of the foreline and its components can further cause this deposition. For example, material can be deposited in multiple focus regions of the foreline at different corresponding rates based on specific conditions associated with each focus region. These conditions may include foreline geometry of that focus region (e.g., structure that may change a direction of the process gas flow and/or converging two or more flows into a common passage), a distance between the processing chamber and a focus region, etc. In another example in which a control valve is in the foreline, the geometry of this valve, and the area around the valve, may cause material may accumulate in the vicinity of the valve at a much higher rate than other sections of the foreline. Gases flowing through the small opening in the adjustable valve can suddenly expand into the foreline, rapidly decreasing in temperature due to adiabatic or near-adiabatic expansion (Joule-Thompson effect). A sudden temperature drop can cause unused deposition precursors in effluent gases to condense on inner wall of foreline and other components of vacuum pumping system. This unwanted deposition can have numerous unwanted effects, such as clogging the conduits, clogging the flow control elements thereby preventing them from functioning properly, or at all, and adversely affecting the flow and pressure within the foreline and processing chamber interior.

Many techniques for removing unwanted deposition in forelines are unable to adequately remove the deposition. For example, some semiconductor processing tools perform cleaning operations that flow a plasma through the processing chamber and into the foreline. These cleaning operations can clean components or features in the processing chamber and in the foreline, however such operations may not be effective at cleaning the foreline and may have adverse effects on the processing chamber. For example, the efficacy of plasma for removing material in the foreline may be based on a plasma flow rate (units of volume or mass per unit of time), a duration of the plasma flow, an amount that free radicals in the plasma have already recombined prior to reaching material in focus regions of the foreline, and the like.

Because some regions in the foreline may have higher material deposition rates than other regions adequately cleaning these regions may use plasma flow from the chamber at a higher flow rate and/or for a longer duration than what are required for cleaning only the processing chamber. These flow conditions may unnecessarily expose chamber surfaces to plasma longer or more intense than required to clean those surfaces, thus potentially damaging them. Alternatively, such focus regions may be incompletely cleaned during each cleaning cycle and may develop a clog or other defect due to the material that builds up over time.

Provided herein are new and novel techniques for reducing and removing deposition in a foreline. Some implementations have a foreline flow control valve that uses a gate with an orifice (e.g., a through-hole) that provides a flow path through the valve having few obstructions and causing less deposition than flow around an outer region of the valve. In some instances, while this valve with the orifice is in a closed position, the valve acts as a flow restrictor which creates a back pressure in the foreline. The back pressure may provide a gradual pressure reduction of gases which can prevent sudden expansion of the gases and thereby prevent or reduce unwanted condensation and deposition of materials in the foreline. Some implementations may also have a catcher downstream of the foreline flow control valve that is configured to provide an accumulation surface for the unwanted deposition. This accumulation surface is positioned within the foreline such that the gases in the foreline flow onto the accumulation surface and deposit there instead of other areas in the foreline. The catcher can be more easily cleaned and/or replaced.

In some embodiments, a ballast gas is flowed into the foreline network to provide flow conditions in the foreline network that reduce and prevent unwanted deposition. The ballast gas may be injected using a gas diffuser or a gas muffler, both of which can reduce unwanted shear and turbulent gas flows which causes material deposition. Some embodiments also provide advantageous pressure control of the processing chamber interior by using, at least in part, the ballast gas flow into the foreline. The ballast gas flow into the foreline can also create a back pressure, or boost the pressure in the foreline, which can control the pressure within the processing chamber and enable the processing chamber pressure to be maintained within a desired pressure range.

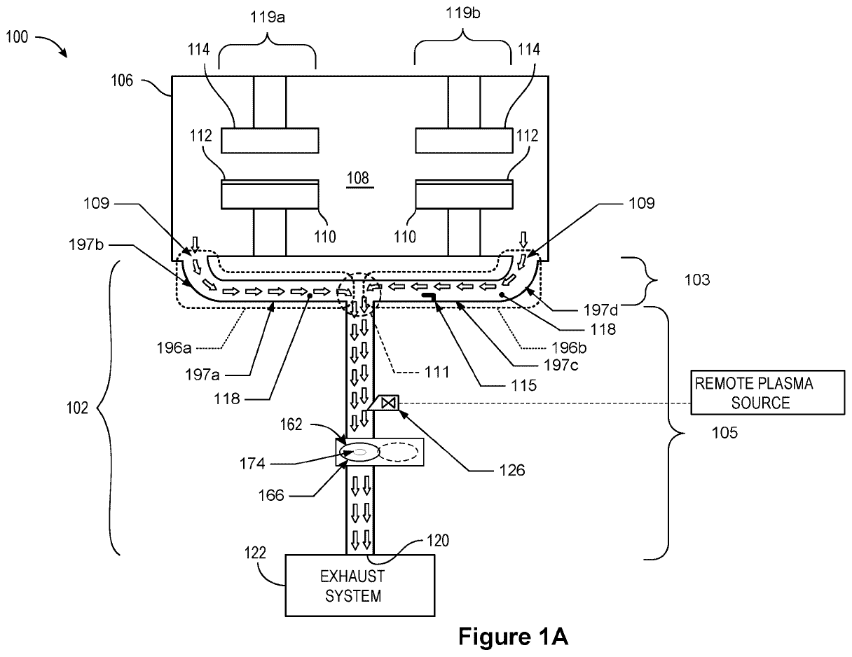

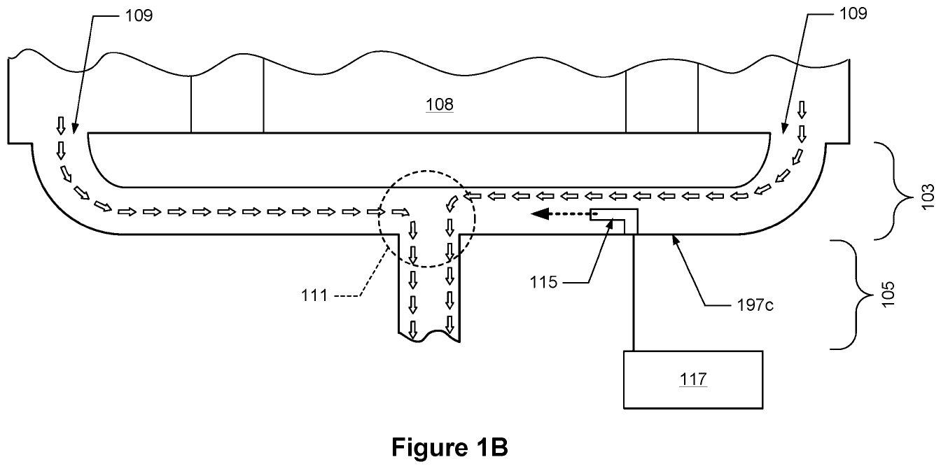

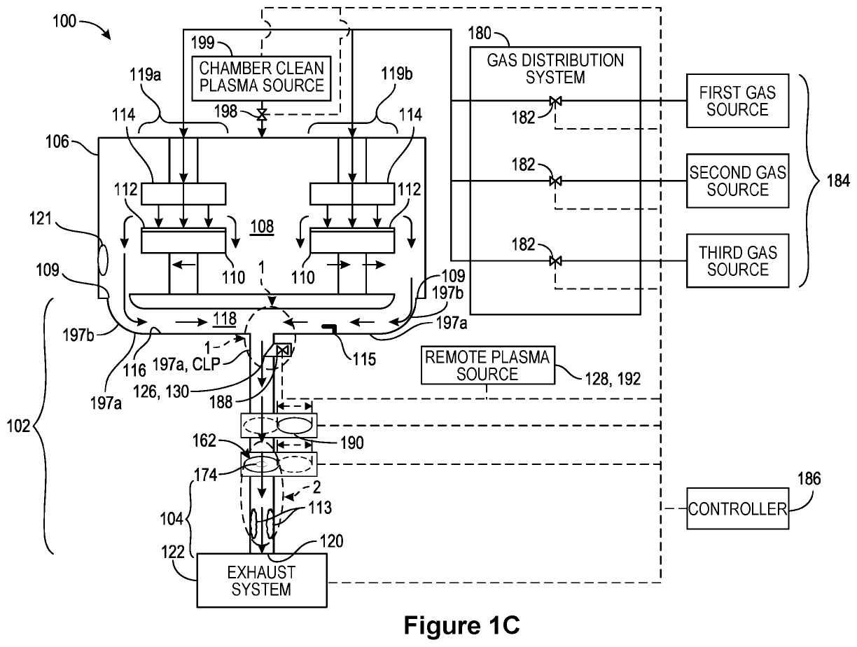

FIG. 1A depicts a semiconductor processing system according to various implementations. The semiconductor processing system 100 may be a chemical deposition system, a chemical vapor deposition (CVD) system, a plasma-enhanced chemical vapor deposition (PECVD) system, an atomic layer deposition (ALD) system, an etching system, an atomic layer etching (ALE) system, or a system configured to perform both deposition and etching. The system 100 has processing chamber 106 with an interior volume 108 and one or more exhaust ports 109. The system 100 also includes two processing stations 119a and 119b that each have one or more wafer supports 110 positioned within the interior volume 108 and configured to support corresponding substrates 112 during one or more semiconductor processing operations (e.g., a deposition process, a preparation process, a heat treatment process, etc.) conducted in the interior volume 108. In this implementation, the semiconductor processing system 100 further includes one or more showerheads 114 (e.g., a flush-mount showerhead, a chandelier-type showerhead, etc.) positioned above the wafer support 110; and the showerheads 114 may be used to flow one or more process gases onto the substrate 112 during processing operations.

The system 100 also includes a foreline 102 configured to receive process gases and materials from the exhaust ports 109 of the processing chamber 106. The foreline 102 has a foreline network 103 that has a plurality of conduits that are fluidically connected to a single common outlet conduit, i.e., foreline outlet conduit 105. As shown, the foreline network 103 has a first segment 196a, encompassed by a dotted shape, that defines a flow path from one exhaust port 109 to a junction 111 where two or more segments join. The first segment has a first non-linear section 197b and a linear section 197a. The foreline network 103 has a second segment 196b that defines a flow path from another exhaust port 109 to the junction 111. The second segment 196b has a first non-linear section 197d and a linear section 197c. Gas flow from the process chamber enters the foreline 102 in the exhaust ports and flows through the interior 118 of the foreline 102 to the common outlet conduit 105 and to the exhaust system 122 as indicated by the arrows.

The foreline 102 includes a foreline walls defining an interior 118 fluidically connected with the interior volume 108 of the processing chamber 106. In this implementation, the foreline 102 is made of stainless steel and/or aluminum alloy components; the interior of the foreline 102 may also have an aluminum or aluminum alloy coating which can prevent or reduce unwanted deposition. The foreline 102 further includes an exhaust interface 120 configured to fluidically connect with an exhaust system 122 (e.g., a vacuum device, a pump device, etc.). The interior 118 provides a conduit that is configured to flow, during the one or more semiconductor processing operations, one or more process gases from the interior volume 108 of the processing chamber 106 to the exhaust system 122.

The system 100 also includes an adjustable or control valve in the foreline that is configured to control gas flow through the foreline. Many plasma-assisted deposition and etching processes may be performed at various pressures and an adjustable valve may be employed between the chamber and the foreline outlet conduit. An adjustable valve may facilitate regulation of chamber pressure at working levels while leaking process gas effluent into a vacuum pumping system or exhaust system. For example, an adjustable valve may be a throttle valve, a pendulum valve, a butterfly valve, or a gate valve. These terms may be used synonymously herein.

Here in FIG. 1A, the control valve is a throttle valve, which may be a pendulum valve 162 with a movable gate 166 having an orifice 174. The orifice 174 may be configured to reduce fouling, e.g., caused by material build-up associated with a tortuous flow path and a higher flow velocity. The orifice 174 is located in a center region of the gate 166 so as to generally maintain a flow direction and flow rate of a portion of the process gases flowing along an inner core space of the foreline interior 118 spaced radially inward from the foreline wall 116. The pendulum valve 162 may support a large conductance range absent the orifice 174. When operating to control pressure and/or flow upstream of the valve 162, the gate 166 is in one or more open positions. In some such open positions, the flow around an outer region of the gate 166 may cause turbulence to the gas and cause unwanted deposition on the gate 166 and the structures around the gate 166. In some embodiments, as discussed in more detail below, the gate 166 may be in a closed position during some processing operations, such as deposition, etching, or both, and thereby cause gas flowing through the foreline 102 to flow through the orifice 174. By having the gate 166 in the closed position, unwanted deposition on the gate, such as its outer regions, and the surrounding structures is reduced or eliminations. FIG. 1A depicts the gate 166 in the closed position such that the gas flow through the foreline outlet conduit 105 is through the orifice 174. Various implementations of the valve 162 are discussed below.

In some embodiments, the gate 166 may have a surface having aluminum which is configured to reduce recombination of the radicals that flow through the foreline. In some instances, the gate may have an aluminum coating over other materials, such as stainless steel, while in other instances, the whole gate may be made of a hard anodized aluminum alloy also configured to reduce recombination of the radicals that flow through the foreline.

Some embodiments have a remote plasma source interface (RPS interface) fluidically connected to the foreline. In FIG. 1A, RPS interface 126 is fluidically connected to foreline 102, and fluidically connected to the foreline outlet conduit 105. As shown in FIG. 1A, the RPS interface 126 is on the foreline outlet conduit 105 such that remote plasma from the remote plasma source flows into the foreline 102 through the RPS interface 126 in the foreline outlet conduit 105. The remote plasma flowed into the foreline 102 may clean components downstream of the RPS interface 126. As shown, the valve 162 is interposed between the RPS interface 126 and the exhaust interface 120 such that the remote plasma from flowed through the RPS interface 126 into the foreline 102 can contact and clean the gate 166 and valve 162 structures. In some implementations, the RPS interface 126 is positioned near and/or having an exit vector pointed at a focus region with a first threshold rate of deposition, which may be higher than the rate of deposition. Various implementations of the RPS interface 126 are discussed below.

As mentioned above, some implementations may have one or more gas injectors in the foreline for injecting ballast gas into the foreline. This gas injection into the foreline can help prevent and reduce material deposition in the foreline, control pressure in the foreline and interior volume, or both. As explained in more detail below, flowing the ballast gas into the foreline enables the valve 162 with the orifice 174 to remain closed during processing operations and reduce unwanted deposition on the valve 162. Having the valve in the closed position during processing operations also advantageously provides back pressure upstream of the valve 162 in the foreline outlet conduit 105 and the foreline network 103. By acting as a flow restrictor or orifice plate, the valve 162 causes a flow resistance that creates this back pressure. The back pressure may provide a gradual pressure reduction of gases transiting from the chamber interior volume 108 through the foreline 102 which prevents sudden expansion of the gases and thereby prevents or reduces unwanted condensation and reaction of constituents in the gases and deposition of materials in the foreline. The back pressure may be at least 5 Torr or higher.

By having the valve 162 in the closed position, it does not actively control or maintain pressure upstream in the foreline 102 and interior volume 108. Rather, the valve 162 with the orifice 174 acts as orifice plate, or flow restrictor. The ballast gas flow into the foreline 102 advantageously boosts the pressure in the foreline network 103 and allows for active pressure control of the foreline and chamber interior volume 108 while the valve 162 is closed. This ballast gas flow also provides active pressure control functionality while reducing and removing some unwanted deposition in the foreline 102. In FIG. 1A, the gas injector 115 is positioned in linear section 197c of the foreline network 103.

FIG. 1B depicts a magnified section of a portion of the system of FIG. 1A. Here, a bottom portion of the processing chamber 106, the interior volume 108, and the exhaust ports 109 are shown along with the foreline network 103 and a portion of the foreline outlet conduit 105. In the depicted embodiment, the system 100 also has a gas injector 115 positioned in the foreline 102 which here, is in the foreline network 103. For illustration purposes, the gas injector 115 is shown in linear section 197c of the second segment. The gas injector 115 is fluidically connected to a ballast gas source 117 which may be an inert gas such as nitrogen, argon, or helium, for example. The flow of ballast gas, represented by the dotted arrow coming out of the gas injector 115, may cause a back pressure in the foreline 102 upstream of the gas injector 115 which can be used to control the pressure in the interior volume 108. Various implementations of the gas injector are provided farther below.

FIG. 1C depicts the semiconductor processing system 100 of FIG. 1A according to various implementations. Here, additional or alternative features are illustrated for FIG. 1A. The system 100 has the foreline 102 configured to clean one or more focus regions 104 of the foreline 102 during a foreline cleaning operation. The foreline 102 includes a foreline wall 116 defining an interior 118 fluidically connected with the interior volume 108 of the processing chamber 106. In this implementation, the foreline 102 is made of stainless steel and/or aluminum alloy components. The foreline 102 further includes an exhaust interface 120 configured to fluidically connect with an exhaust system 122 (e.g., a vacuum device, a pump device, etc.). The interior 118 provides a conduit that is configured to flow, during the one or more semiconductor processing operations, one or more process gases from the interior volume 108 of the processing chamber 106 to the exhaust system 122.

The flow of process gases through the foreline 102 may cause material 113 from the flow of process gases to be deposited in multiple focus regions 104 of the foreline 102 at different corresponding rates based on specific conditions associated with each focus region.

These conditions may include foreline geometry of that focus region (e.g., structure that may change a direction of the process gas flow and/or converging two or more flows into a common passage), a distance between the processing chamber 106 and a focus region, etc. For example, the foreline 102 may branch into multiple segments 196 including multiple linear sections 197a that each define a linear portion of the corresponding flow path through the foreline 102 and multiple non-linear sections 197b (e.g., arcuate elbow sections) that each define a non-linear portion of the corresponding flow path through the foreline 102. The non-linear sections 197b are configured to redirect the corresponding flow path and may thus cause free radicals in the plasma to interact with those non-linear sections 197b at a rate higher than the rate at which the radicals may interact with the linear sections 197a. As another example, one of the linear sections 197a may define a common linear portion CLP of two or more flow paths being redirected from two other corresponding linear sections 197a. The separate flows originating from different exhaust ports 109 of the processing chamber 106 may combine in the common linear portion CLP so as to deposit material in the common linear portion CLP. Other conditions that may affect the rate of material deposition may include a process gas flow rate (units of volume or mass per unit of time), a duration of the process gas flow, the composition of the process gases, the composition of the foreline, and the like.

In some cases, a foreline flow adjustment valve, such as a throttle valve or the pendulum valve 162, may be disposed downstream of the non-linear sections 197b, e.g., at a part of the foreline 102 that receives process gas from all of the exhaust ports 109, such that gas flow for all upstream segments of the foreline may be regulated by that foreline flow adjustment valve. Due to the geometry of such a valve, material may accumulate in the vicinity of the valve at a much higher rate than in both the linear sections 197a and the non-linear sections 197b of the foreline 102. The area around the valve may be associated with multiple conditions (e.g., a bottleneck of all process gases, both foreline geometry and valve geometry interrupting flow, etc.) that collectively interrupt flow and may thus contribute to deposition of material more than in other areas of the foreline 102. Moreover, in forelines for multi-station chambers, such a valve may effectively be subjected to potential deposition rates that are multiple times higher than the upstream segments of the foreline may be subjected to. For example, in a four-station chamber in which each station has a separate exhaust port connected with a corresponding foreline segment, each time the gas flows from two separate sections of foreline combine into one downstream foreline section, the amount of deposition gas exposure that the downstream section sees may be on the order of twice as high as either upstream section of the foreline sees. Thus, at the point where the flow adjustment valve may be located in such a system, the exposure rate to deposition-forming gas may be several times higher than in the upstream sections of the foreline.

The semiconductor processing system 100 may further include a chamber cleaning plasma source 199 fluidically connected with the processing chamber 106 and configured to flow plasma into the processing chamber 106 to clean components or features in the processing chamber 106. The foreline 102 may be configured to evacuate the plasma from the processing chamber 106. While plasma from the chamber cleaning plasma source 199 primarily cleans components or features in the processing chamber 106, the plasma may also remove material 113 deposited within the foreline 102. The efficacy of plasma for removing material in the foreline 102 may be based on a plasma flow rate (units of volume or mass per unit of time), a duration of the plasma flow, an amount that free radicals in the plasma have already recombined prior to reaching material in focus regions of the foreline 102, and the like. As described above, some focus regions may have higher material deposition rates than other regions and may thus experience deposition of thicker layers of material than those of other regions within a given time interval. To completely remove material from such focus regions having higher material deposition rates, the semiconductor processing system 100 may cause plasma from the chamber cleaning plasma source 199 to flow at a higher flow rate and/or for a longer duration than what are required for cleaning only the processing chamber 106. These flow conditions may unnecessarily expose chamber surfaces to plasma longer or more intense than required to clean those surfaces, thus potentially damaging them. Alternatively, such focus regions may be incompletely cleaned during each cleaning cycle and may develop a clog or other defect due to the material that builds up over time.

Build-up of material in the foreline 102 may be removed without damaging the chamber surfaces by using a second plasma source separate from the chamber cleaning plasma source 199 and configured to flow a cleaning plasma directly into the foreline 102. As described in detail below, the foreline 102 includes a remote plasma source interface 126 (RPS interface) positioned near and/or having an exit vector pointed at a focus region 104 with a first threshold rate of deposition, which may be higher than the rate of deposition in one or more of the other regions of the foreline 102. In one implementation, the first threshold rate of deposition may be larger than the rate of deposition in all of the other regions of the foreline. In other implementations, the first threshold rate of deposition may be smaller than the rate of deposition in one or more of the other focus regions of the foreline when the system has other features that clean or prevent build-up in those focus regions.

The RPS interface 126 is configured to fluidically connect with a remote plasma source 128, such that plasma from the remote plasma source 128 is configured to flow into the foreline 102 via the RPS interface 126 without first flowing through the interior volume 108 of the processing chamber 106. The RPS interface 126 is fluidically interposed between the interior volume 108 of the processing chamber 106 and the exhaust interface 120, and more specifically between the interior volume 108 of the processing chamber 106 and one or more focus regions 104 of the foreline 102 on which material 113 is deposited in high concentrations. In this implementation, the remote plasma source 128 is configured to produce plasma with oxygen and/or fluorine (i.e., producing oxygen and/or fluorine radicals, etc.), but other suitable gases may be used instead. The RPS interface 126 is located within a predetermined distance of the one or more focus regions 104 and/or is configured to direct plasma to those focus regions 104 so as to reduce or eliminate the amount of the plasma lost to recombination (e.g., associated with the plasma interacting with the processing chamber 106 and the foreline wall 116) and conserve the efficacy of plasma for removing material 113 from the one or more focus regions 104 having the highest buildup of material 113. Plasma from the chamber cleaning plasma source 199 may be introduced into the processing chamber 106 to remove deposited material from surfaces in the processing chamber 106, while a second plasma from the remote plasma source 128 is introduced into the foreline 102 via the RPS interface 126 to remove deposited material in the foreline 102. If the chamber plasma clean finishes before the foreline plasma clean finishes, the flow of plasma into the processing chamber 106 may be stopped and the flow of plasma through the RPS interface 126 may be continued to finish cleaning the foreline 102 without unnecessarily subjecting the chamber surfaces to additional plasma exposure.

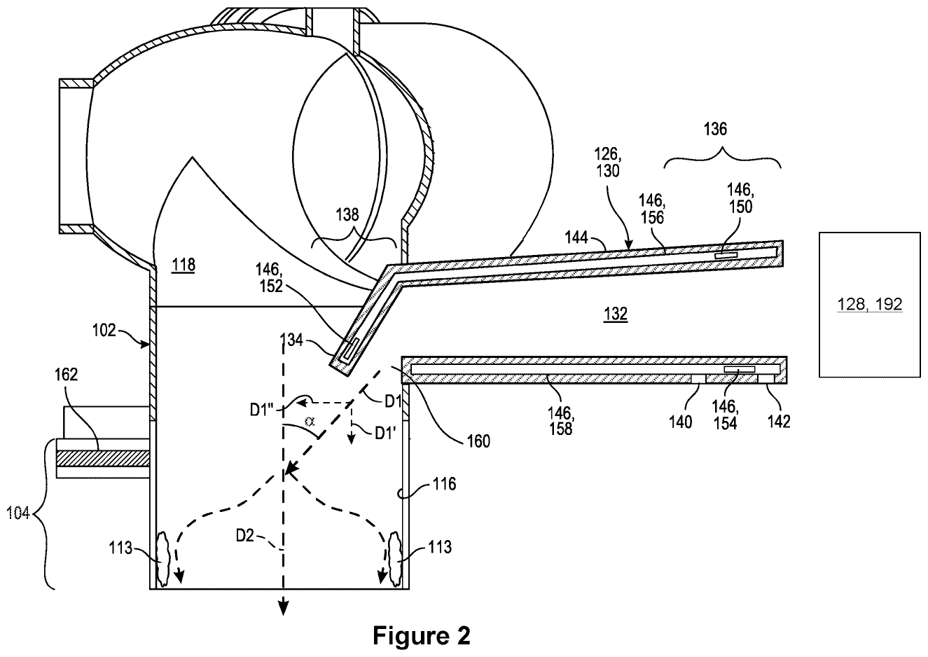

FIG. 2 depicts an enlarged cutaway view of an example portion of the semiconductor processing system of FIG. 1C, as taken from Region 1. In this implementation, the RPS interface 126 includes a nozzle 130 having a first surface facing radially inward toward a central axis and defining a plasma passage 132 fluidically interposed between the remote plasma source 128 and the foreline 102. The plasma passage 132 is configured to direct, during the foreline cleaning operation, the plasma along a direction D1 having a component D1′ that parallels a downstream direction D2 of the foreline 102 and another component D″ that is perpendicular to the direction D2. In some embodiments, the downstream direction D2 may be parallel, or substantially parallel, to the center axis of the foreline conduit or foreline wall 116. One or more of the focus regions 104 of the foreline 102 on which material 113 is deposited may be located along the direction D1 from the RPS interface 126, such that plasma from the RPS interface 126 is able to reach such material 113 in a more direct manner, thereby reducing the chance that radicals in the plasma will recombine prior to reaching the material 113. The cleaning efficacy of the plasma (e.g., oxygen and fluorine radicals, etc.) may thereby be conserved for removing the material 113.

The plasma passage 132 may be configured to direct the plasma, during the foreline cleaning operation, along a direction that is at a predetermined angle between a first end point and a second end point relative to the foreline wall 116 (inclusive of the first end point and the second end point). In this implementation, the plasma passage 132 may be configured to direct the plasma, during the foreline cleaning operation, along a direction that is at a predetermined angle in a range between 30 degrees and 60 degrees relative to the foreline wall 116 (inclusive of a direction that is 30 degrees relative to the foreline wall 116 and a direction that is 60 degrees relative to the foreline wall 116). In other implementations, the plasma passage 132 may be configured to direct the plasma, during the foreline cleaning operation or other processes, along a direction that is at any angle relative to the foreline wall 116. In some cases where the plasma passage 132 is configured to direct plasma at a direction at less than 30 degrees relative to the foreline wall 116 (e.g., parallel or nearly parallel to the downstream direction D2), the plasma may flow past the area to be cleaned and thus remove less material from that area, as compared to the amount of material removed by plasma directed along a direction at more than 30 degrees relative to the foreline wall 116. However, such configurations may be better suited for removing material build-up that is on the same side of the foreline 102 as the RPS interface 126. In other cases where the plasma passage 132 is configured to direct plasma at a direction at more than 60 degrees relative to the foreline wall 116 (e.g., perpendicular or nearly perpendicular to the downstream direction D2), free radicals in the plasma may recombine closer to the RPS interface 126 and the plasma efficacy downstream of the RPS interface 126 may thus be less than the plasma efficacy of plasma directed along a direction at less than 60 degrees relative to the foreline wall 116. Such implementations may, however, be more useful in situations in which the areas of greatest material build-up is directly across from the RPS interface.

In this implementation, the nozzle 130 has a tip 134 protruding into the interior 118 of the foreline 102, such that the nozzle 130 may introduce plasma into the interior 118 of the foreline 102 at a location spaced radially inward from the foreline wall 116 and the nozzle 130 may direct the flow of plasma in a direction at least somewhat parallel to the foreline wall 116 so as to reduce interactions between the foreline wall 116 and the plasma. In this implementation, the RPS interface 126 may be made of a hard anodized aluminum alloy configured to reduce recombination of the oxygen and fluorine radicals that flow through the plasma passage 132.

The RPS interface 126 (e.g., the nozzle 130) has a first end portion 136 connected with the remote plasma source 128 and a second end portion 138 connected with the RPS interface 126 of the foreline 102. In this implementation, the first end portion 136 may include a lip or a collar that extends radially outward from a central axis of the plasma passage 132 and/or extends circumferentially around and outwardly from an outer surface of the RPS interface 126. The plasma passage 132 of the nozzle 130 may taper from the first end portion 136 toward the second end portion 138 (e.g., along the first end portion 136, up to a portion of the nozzle 130 spaced from the second end portion 138, up to a portion of the nozzle 130 adjacent to the second end portion 138, up to and terminating at an upstream side of the second end portion 138, through the second end portion 138 and terminating at a downstream side of the second end portion 138, etc.). The plasma passage 132 may have a first segment with a first diameter DIA1 in the first end portion 136 and a second segment with a second diameter DIA2 in the second end portion 138, and the first diameter DIA1 of the first segment may be larger than the second diameter DIA2 of the second segment. The plasma passage 132 may be linear through the first end portion 136 and curve at least partially along the second end portion 138 and through the tip 134. The curvature of the plasma passage 132 along the second end portion 138 and through the tip 134 may be configured to direct plasma along the direction D1 as described above. In some implementations, the outer surface of the nozzle 130 may taper in diameter from the first end portion 136 toward the second end portion 138 (e.g., along the first end portion 136, up to a portion of the nozzle 130 spaced from the second end portion 138, up to a portion of the nozzle 130 adjacent to the second end portion 138, up to and terminating at an upstream side of the second end portion 138, through the second end portion 138 and terminating at a downstream side of the second end portion 138, etc.).

As further shown in FIG. 2, the nozzle 130 includes an inlet port 140 and an outlet port 142 both located in the first end portion 136 of a nozzle wall 144. In other implementations, the inlet port 140 and the outlet port 142 may be located in other portions of the RPS interface 126 (e.g., in the second end portion 138, between the first end portion 136 and the second end portion 138, etc.). The inlet port 140 and the outlet port 142 may extend radially outward from plasma passage 132 and/or the outer surface of the RPS interface 126. The inlet port 140 and the outlet port 142 may be located proximate to and/or spaced circumferentially from one another.

The nozzle 130 further includes one or more coolant passages 146 located along the outer surface and in the nozzle wall 144. As can be seen in FIG. 2, the one or more coolant passages 146 define one or more coolant flow paths leading from the inlet port 140 to the outlet port 142 and passing through the second end portion 138.

The one or more coolant passages 146 in the nozzle wall 144 are disposed about the plasma passage 132 and configured to flow coolant (e.g., water, air, etc.). The coolant maintains a temperature of the plasma flowing from the remote plasma source 128 below a predetermined temperature threshold (e.g., 200 degrees Fahrenheit) so as to reduce or prevent thermal damage to the nozzle 130 and/or the foreline 102. The coolant also maintains the temperature of the plasma below the predetermined temperature threshold so as to conserve oxygen in the plasma and reduce recombination of free radicals in the plasma prior to the plasma reaching the focus regions 104 to be cleaned. In this implementation, the one or more coolant passages 146 may include a first plenum 150 in the first end portion 136 and fluidically connected with the inlet port 140. The one or more coolant passages 146 may further include a second plenum 152 in the second end portion 138. The one or more coolant passages 146 may further include a third plenum 154 in the first end portion 136 and fluidically connected with the outlet port 142. The one or more coolant passages 146 may further include a set of one or more first channels or passages 156 fluidically interposed between the first plenum 150 and the second plenum 152 and a set of one or more second channels or passages 158 fluidically interposed between the second plenum 152 and the third plenum 154.

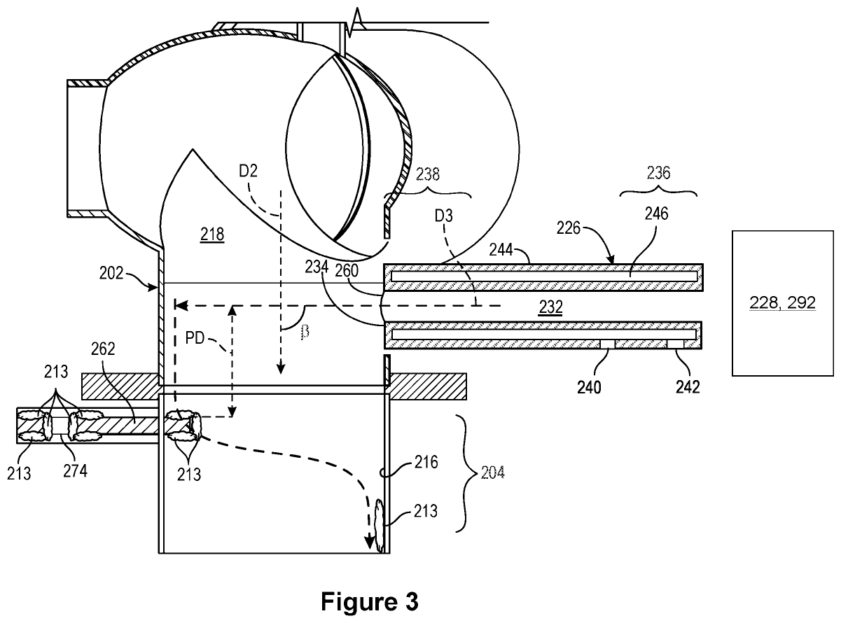

FIG. 3 depicts another example RPS interface 226 that is somewhat similar to the RPS interface 126 of FIG. 2. To avoid undue repetition, elements in the implementation of FIG. 3 that are analogous to elements shown in FIG. 2 are called out with numbers that share the same last two digits as those analogous elements in FIG. 2. Thus, the discussion provided above with respect to the elements of the implementation of FIG. 2 will be understood to be equally applicable to the analogous elements in FIG. 3 unless indicated otherwise. In the interest of conciseness, discussion of these elements that would be redundant of earlier discussion herein of similar elements is not provided, with the understanding that the earlier discussion of such elements is applicable to these similar elements in FIG. 3. This is applicable to any Figure herein, including FIGS. 1A-1C and 7A-8B, for example.

FIG. 3 depicts an enlarged cutaway view of Region 1 of the semiconductor processing system of FIG. 1C. While the RPS interface 126 of FIG. 2 includes the nozzle 130 protruding through an opening 160 defined in the foreline wall 116 and into the interior 118 of the foreline 102, the RPS interface 226 of FIG. 3 terminates at the opening 260 in the foreline wall 216 without protruding into the interior 218 of the foreline 202. The valve 262 in FIG. 3 is in an open position having material 213 deposited thereon. Omitting the RPS interface 226 from the interior 218 of the foreline 202 provides less resistance to the flow of process gases through the foreline 202 and may prevent material from the flow of process gases from being deposited on the RPS interface 226 (or at least reduce the rate at which such deposition may occur).

The plasma passage 232 of FIG. 3 further differs from the plasma passage 132 of FIG. 2 in that the plasma passage 232 is configured to direct plasma along a direction D3 without a component that parallels a downstream direction D2 of the foreline 202; as noted above, this direction D2 may be parallel, or substantially parallel, to the center axis of the foreline 202. In this implementation, the plasma passage 232 may be configured to direct the plasma towards a portion of the foreline wall 216 opposite to the opening 260 and spaced within a predetermined distance PD from a first one of the focus regions 204, such that the introduced plasma is able to quickly reach the focus region(s) 204, thereby avoiding a large reduction in cleaning efficacy of the plasma.

The RPS interface 126 of FIG. 2 includes multiple first channels 156 fluidically interposed in parallel connection between the first plenum 150 and the second plenum 152 and multiple second channels 158 fluidically interposed in parallel connection between the second plenum 152 and the third plenum 154. The RPS interface 226 of FIG. 3 includes a single serpentine coolant passage 246 alternately passing through multiple sections of the first end portion 236 and multiple sections of the second end portion 238. The single serpentine coolant passage 246 has one end fluidically connected with the inlet port 240 and another end fluidically connected with the outlet port 242. The coolant passage 246 includes linear segments extending parallel and adjacent to the plasma passage and U-shaped segments extending circumferentially around and adjacent to the plasma passage 232. The linear segments and the U-shaped segments are fluidically connected with one another. In other implementations, the RPS interface 226 may include multiple serpentine coolant passages (e.g., running parallel with each other, nested with each other, etc.) fluidically connected with a common inlet port (e.g., the inlet port 240) and a common outlet port (e.g., the outlet port 242). In still other implementations, the RPS interface 226 may include alternative arrangements of the coolant passages fluidically connected with separate inlet ports and/or separate outlet ports and/or with one or more segments that are concentric and/or coaxial with the plasma passage 232.

The RPS interface 226 may have a cylindrical body with the plasma passage 232 including a tapered segment located in the first end portion 236 along the RPS interface 226. The plasma passage 232 may further include a linear segment fluidically connected with the tapered segment. The linear segment may extend at least partially along the first end portion 236 and through the second end portion 238.

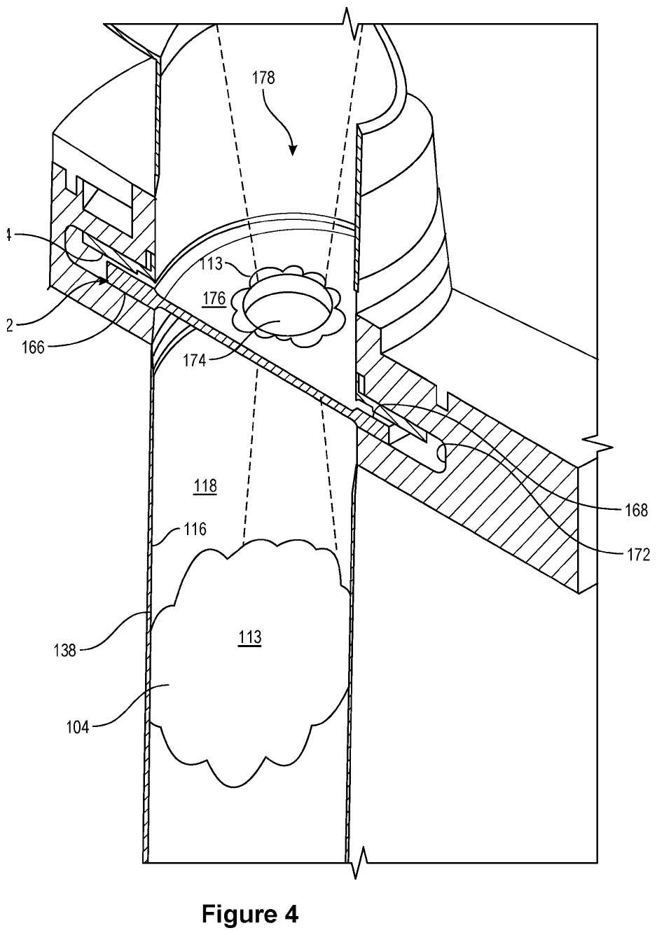

Features of the throttle valve in the foreline according to various implementations will now be discussed. FIG. 4 depicts an enlarged cutaway view of an example portion of the semiconductor processing system 100 of FIG. 1C, as taken from Region 2. As noted above, the valve 162 may be the same valve depicted in the simplified system 100 of FIG. 1A. FIG. 4 depicts the foreline 102 having a pendulum valve 162 with a gate 166 including an orifice 174 configured to reduce fouling, e.g., caused by material build-up associated with a tortuous flow path and a higher flow velocity. The orifice 174 is located in a center region 176 of the gate 166 so as to generally maintain a flow direction and flow rate of a portion of the process gases flowing along an inner core space of the foreline interior 118 spaced radially inward from the foreline wall 116. The pendulum valve 162 may support a large conductance range absent the orifice 174.

When running certain chemical deposition processes in some implementations, the gate 166 may move to one or more small valve angles below a predetermined angle threshold, and may thus require the process gases to flow along the tortuous path (i.e., between an outer edge region 168 of the gate 166 and an inner perimeter of a sealing ring 164 having features configured to be coupled to the foreline 102). The tortuous flow path may increase the likelihood that entrained polymer particles may detach from streamlines and stick to surfaces and foul the pendulum valve 162 while disposed at small angles. Furthermore, in some cases, the chemical deposition process may require the process gases to flow at a high velocities along a tortuous path. This may cause material 113 to be deposited in or near an interface between the outer edge region 168 of the gate 166 and an inner perimeter 178 of the sealing ring 164 and accumulate until the gate 166 seizes. In some implementations, such issues are reduced or minimized by including the orifice 174, which causes a large portion of the process gases to flow through the inner core space of the foreline interior 118 spaced radially inward from the foreline wall 116 and minimizes flow interruption by maintaining flow direction and flow rate within the inner core space. The flow of process gases through the orifice 174 significantly decreases the amount of gases flowing along the tortuous path around the outer edge region 168 of the gate 166 and thus decreases fouling at or near the outer edge region 168. The decreased fouling at or near the outer edge region 168 may in turn prevent the gate 166 from seizing, decrease preventative maintenance of the foreline 102, and conserve uptime and corresponding throughput of the semiconductor processing system 100. In this implementation, the center region 176 of the gate 166 may have a thickness greater than that of the outer edge region 168 of the gate 166. In other implementations, the center region 176 of the gate 166 may have a thickness less than or equal to that of the outer edge region 168 of the gate 166.

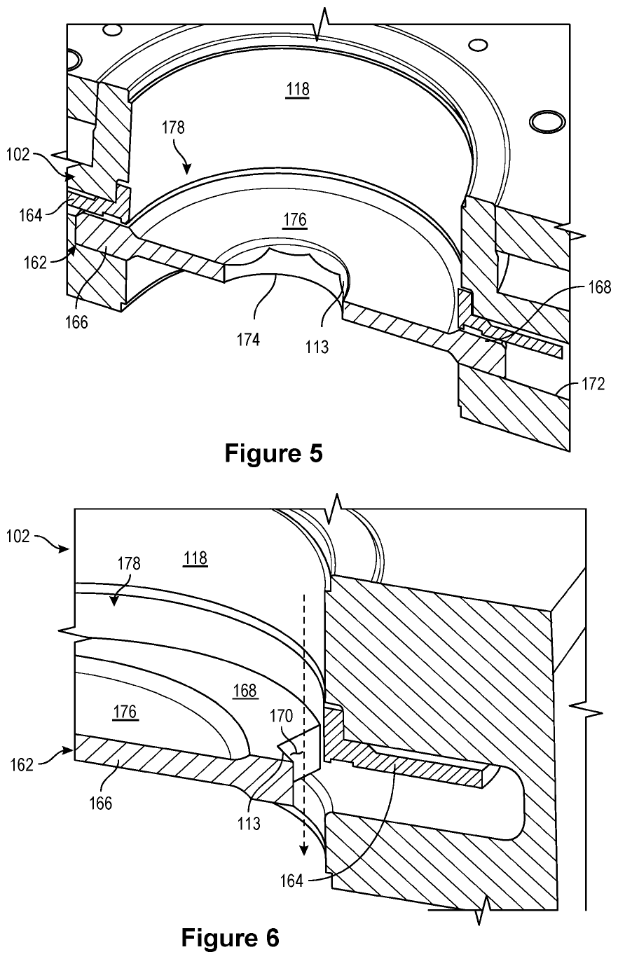

In this implementation, the pendulum valve 162 is fluidically interposed between the RPS interface 126 and the exhaust interface 120. As best shown in FIGS. 4-6, the sealing ring 164 is coaxially positioned with the foreline 102. The gate 166 is movable, relative to the seat 172 and the sealing ring 164, between a first position (i.e., the closed position of FIGS. 4 and 5) where the outer edge region 168 sealingly engages with at least a portion of the sealing ring 164 and a second position (i.e., an open position illustrated in FIG. 6) where that portion of the outer edge region 168 is displaced radially inward from the inner perimeter 178 of the sealing ring 164. As provided herein, the gate 166 is movable in a plurality of open positions, one of which is shown in FIG. 6. The valve 162 is configured to control pressure in the foreline 102 and chamber interior volume 108 by positioning the gate in various open positions to restrict the flow through the foreline 102. As discussed herein, then the gate 166 is positioned in the closed position illustrated in FIGS. 4 and 5, the gate 166 and orifice 174 act as an orifice plate that provides a constant flow restriction. The foreline includes a seat 172 configured to receive the portion of the outer edge region 168 when the gate 166 is in the first position (FIGS. 4 and 5), such that at least a portion of the sealing ring 164 sealingly engages with the portion of the outer edge region 168 and directs all the process gases through the orifice 174. The foreline 102 is not limited to pendulum valves for flow control or adjustment and may use other valves having a gate with an orifice (e.g., a linear gate valve) in place of the pendulum valve 162.

FIG. 5 depicts an enlarged view of the pendulum valve of FIG. 4 and FIG. 6 depicts an enlarged view of the pendulum valve of FIG. 5. As shown, in some embodiments, the pendulum valve 162 may have a notch 170 at the outer edge region 168 of the gate 166 so as to flow a portion of the process gas when the gate 166 is moved by small angular movements from the first position (FIG. 5) toward the second position (FIG. 6) and permit the pendulum valve 162 to precisely control and gradually adjust the flow rate. The flow of process gases through the pendulum valve 162 may be distributed between the orifice 174 and the notch 170 when the gate 166 is in the second position, such that the pendulum valve 162 experiences less fouling at the outer edge region 168 of the gate 166, as compared to the amount of fouling associated with a gate not having the orifice and requiring all the process gases to flow along a tortuous path around the outer edge region of the gate. The plasma passage 232 of the RPS interface 226 (FIG. 3) may be configured to direct plasma generally towards the location where the outer edge region 168 of the gate 166 is in when the gate 166 is in the second position.

The semiconductor processing system is configured to set or adjust chamber pressure of the processing chamber 106 when the gate 166 is in the first position where at least a portion of the sealing ring 164 sealingly engages at least a portion of the outer edge region 168 so as to block the flow of process gases through an interface between the outer edge region 168 and the inner perimeter 178 of the sealing ring 164 and require all process gases to flow through the orifice 174. In this implementation, as shown in FIG. 1C, the semiconductor processing system further includes a gas distribution system 180 having a plurality of valves 182 controllable to selectively cause one or more process gases from a plurality of different gas sources 184 connectable to the gas distribution system 180 to be flowed into the processing chamber 106 and then through the orifice 174 of the pendulum valve 162. The system of FIGS. 1A and 1B may have these features and they are not shown for clarity.

The semiconductor processing system 100 further includes a controller 186 configured to control the valves 182 of the gas distribution system 180 to cause the one or more process gases to be flowed into the processing chamber 106 to adjust the chamber pressure associated with all process gases flowing through the orifice when the gate 166 is in the first position. The controller 186 is further configured to control the valves 182 of the gas distribution system 180 to not cause the one or more process gases to be flowed into the processing chamber 106 during the foreline cleaning operation. In this implementation, the semiconductor processing system 100 further includes the remote plasma source 128 and a foreline plasma valve 188 fluidically interposed between the remote plasma source 128 and the RPS interface 126 of the foreline 102. The controller 186 is configured to control the remote plasma source 128 and the foreline plasma valve 188 to cause the plasma from the remote plasma source 128 to be flowed into the foreline 102 during the foreline cleaning operation.

The controller 186 is further configured to control the foreline plasma valve 188 to block the one or more process gases from flowing through the RPS interface 126 and into the remote plasma source 128 so as to prevent material from the process gases from being deposited in the RPS interface 126. The semiconductor processing system 100 may further include the chamber cleaning plasma source 199 (separate from the foreline cleaning plasma source 192) and a chamber plasma valve 198 fluidically interposed between the chamber cleaning plasma source 199 and the interior volume 108 of the processing chamber 106. The controller 186 is configured to control the chamber cleaning plasma source 199 and the chamber plasma valve 198 to cause the plasma from the chamber cleaning plasma source 199 to be flowed into the interior volume 108 of the processing chamber 106 during the chamber cleaning process. The controller 186 is further configured to control the chamber plasma valve 198 to stop the flow of plasma into the interior volume 108 of the processing chamber 106 to avoid unnecessarily subjecting the chamber surfaces to additional plasma exposure (e.g., when the chamber surfaces have been cleaned and the foreline plasma valve 188 continuous to flow plasma into the foreline 102 and downstream to the exhaust interface).

The semiconductor processing system 100 further includes a gate valve 190 fluidically interposed between the RPS interface 126 and the pendulum valve 162, with the gate valve 190 being configured to move between an open position where the gate valve permits flow through the foreline 102 and a closed position where the gate valve 190 completely blocks all flow through the foreline 102. In this implementation, the gate valve (and not the pendulum valve 162) may be used to completely block all flow through the foreline 102 because the orifice 174 in the gate 166 of the pendulum valve 162 allows some flow even when the gate 166 is in the first position. However, in other implementations, the gate valve 190 may be downstream of the pendulum valve 162 or upstream of the RPS interface 126. In still other implementations, the foreline 102 may not include the gate valve 190.

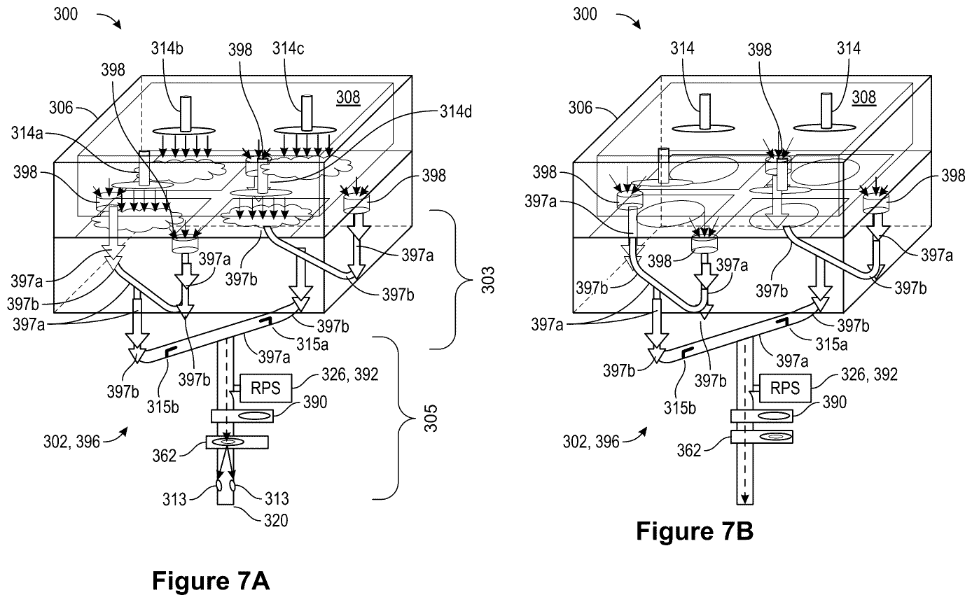

In some embodiments, the systems provided herein may have a foreline with more branches than illustrated in FIGS. 1A-1C. For example, additional branches may be used when a processing chamber has more than two processing stations and/or more than two exhaust ports. FIG. 7A depicts a schematic diagram of another example semiconductor processing system in one configuration and FIG. 7B depicts the example semiconductor processing system of FIG. 7A in a second configuration. The system 300 shown in FIGS. 7A and 7B is somewhat similar to the semiconductor processing system 100 of FIGS. 1A-1C. To avoid undue repetition, elements in the implementation of FIGS. 7A and 7B that are analogous to elements shown in FIGS. 1A-1C are called out with numbers that share the same last two digits as those analogous elements in FIGS. 1A-1C. Thus, the discussion provided above with respect to the elements of the implementation of FIGS. 1A-1C will be understood to be equally applicable to the analogous elements in FIGS. 7A and 7B unless indicated otherwise. In the interest of conciseness, discussion of these elements that would be redundant of earlier discussion herein of similar elements is not provided, with the understanding that the earlier discussion of such elements is applicable to these similar elements in FIGS. 7A and 7B. For example, valve 362 corresponds to valve 162 and gas injectors 315a and 315b correspond to gas injector 115.

The semiconductor processing system 300 of FIGS. 7A and 7B is a multi-station processing chamber with four processing stations in the chamber interior volume 308. As noted herein, multi-station chambers are not limited to four stations and may include fewer or more stations, such as 3, 5, 6, 7, 8, 9, or 10 stations in one chamber. In FIG. 7A, the processing chamber 306 has four processing stations in the chamber interior volume 308 and for clarity, these stations are not labeled. The four showerheads 314a-314d of each of the four stations are identified along with four exhaust ports 398. The foreline 302 branches into more segments 396 that define flow paths fluidically connected with and leading to different exhaust ports 398. The segments 396 include multiple linear sections 397a that each define a linear portion of the corresponding flow path through the foreline 302 and multiple non-linear sections 397b (e.g., arcuate elbow sections) that each define a non-linear portion of the corresponding flow path through the foreline 302. The RPS interface 326 is fluidically interposed between at least one of the non-linear portions of the corresponding flow paths and the exhaust interface 320. More specifically, in this implementation, the RPS interface 326 is fluidically interposed between all of the non-linear portions of the flow paths and the exhaust interface 320. The RPS interface is positioned along the foreline outlet conduit 305. As can also be seen, system 300 includes two gas injectors 315a and 315b positioned in the foreline 302, such as in the foreline network 303 and upstream of the foreline outlet conduit 305.

In FIG. 7A, one or more processing operations are being performed in the four stations in the interior volume 308. The one or more processing operations may be depositing material onto substrates via CVD, PECVD, ALD, for example, or etching material from substrates, such as via ALE. During these depositing and/or etching operations, ballast gas may be flowed into the foreline 302 through gas injectors 315a and 315b to prevent unwanted deposition in the foreline and control pressure in the interior volume 308. As further illustrated in FIG. 7A, during these operations the valve 362 is positioned in the closed position thereby acting as a flow restrictor or orifice plate and providing a constant restriction against the flow from the chamber interior volume 308. The gases flowing through the foreline 302 flow through the orifice of the valve 362. Placing valve 362 in the closed position during the processing operations advantageously reduces and prevents unwanted deposition on aspects of the valve 362, the valve 362 is unable to move and provide active pressure control for the foreline 302 and chamber interior volume 308. The valve 362 in the closed position also creates back pressure upstream of the valve which can also provide a gradual pressure drop within the foreline 302 and thereby reduce unwanted condensation and deposition of material in the foreline 302. As discussed in more detail herein, injecting the ballast gas through the gas injectors 315a and 315b during the processing operations while the valve 362 is in the closed position advantageously provides active pressure control of the foreline 302 and chamber interior volume 308 as well as preventing and reducing unwanted deposition in the foreline 302.

In FIG. 7B, one or more other operations are being performed in the chamber 306.

This can include cleaning, pre-processing operations, or post-processing operations. A cleaning operation can include flowing plasma in the stations, chamber interior volume 308, and also into the foreline 302 through the RPS interface 326. During these other operations, the valve 362 can operate to actively control the flow and pressure in the foreline 302 and chamber interior volume 308 by moving the gate in one or more open positions. During this cleaning, the plasma removes the material deposited near the orifice of the valve 362.

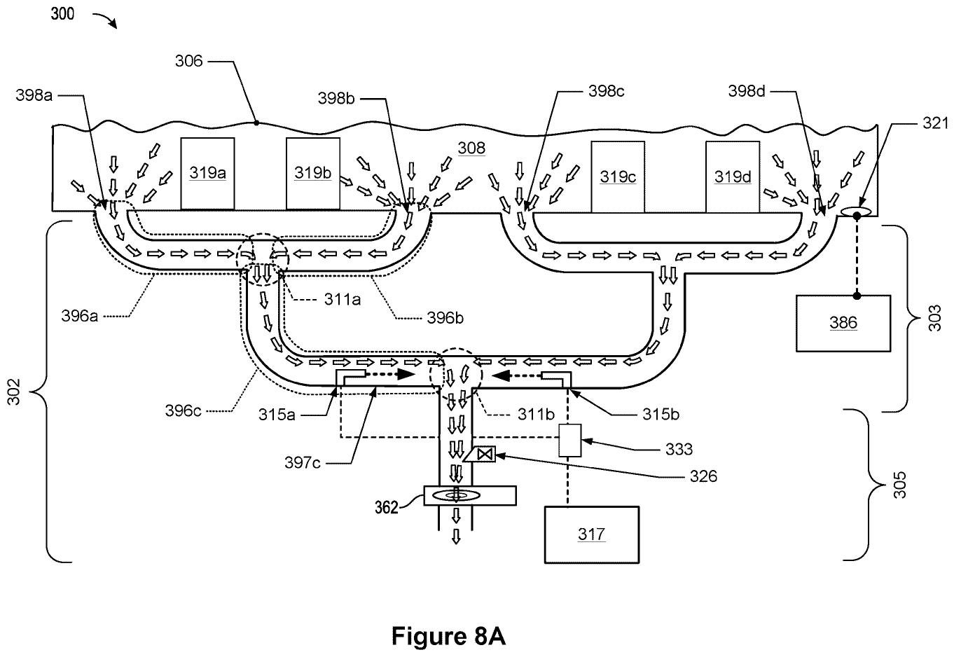

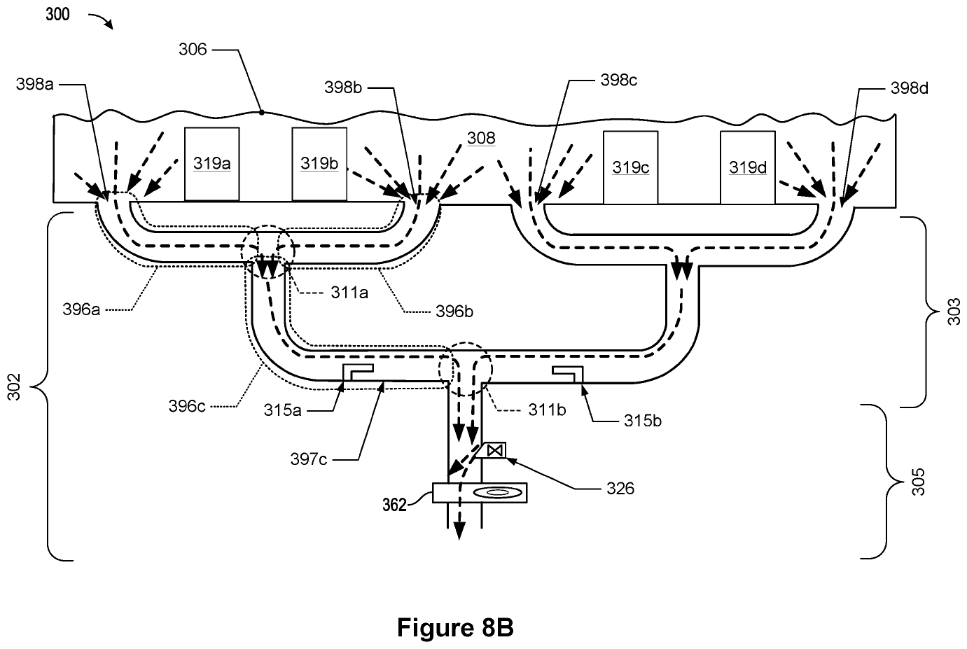

FIG. 8A depicts a simplified magnified schematic of the system of FIG. 7A. Here, the portion of the system 300 includes the chamber interior volume 308, four exhaust ports 398a-398d, and four processing stations that are represented by boxes 319a-319d. FIG. 8A depicts the system 300 during the one or more processing operations, such as depositing or etching, and with the valve 362 is in the closed position and ballast gas flowing through the gas injectors 315a and 315b. The gases from the chamber interior volume 308 are represented by the white arrows and as can be seen, these gases enter the foreline via exhaust ports 398a-398d; these may be the same as exhaust ports 109 in FIGS. 1A-1C. The foreline network 303 of the foreline 302 has a plurality of branches that define various flow paths, such as a first segment 396a spanning between exhaust port 398a and junction 311a and second segment 396b spanning between exhaust port 398b and junction 311a. Downstream of the junction 311a is another segment 396c that spans between the junction 311a and another junction 311b and downstream from this junction 311b is the common foreline outlet conduit 305. The gas injector 315a is positioned within a conduit, identified as linear section 397c, of this third segment downstream of the junction 311a and before the common foreline outlet conduit 305. Placing the gas injector 315a in this location can advantageously provide uniform pressure along the upstream segments 396c, 396a, and 396b and exhaust ports 398a and 398b. This placement enables a single injector to provide uniform back pressure and flow for one half of the foreline network and processing chamber 306 and interior volume 308. The other portion of the foreline network 303 is similarly configured, but not labeled for clarity.

As mentioned, the valve 362 in the closed position can create back pressure upstream of the valve 362 which can also provide a gradual pressure drop within the foreline 102 as compared to the chamber pressure. This back pressure can create a high-pressure environment in the foreline 102 close to, but less than, the chamber pressure and also reduce unwanted condensation and deposition of material in the foreline 102.

FIG. 8B depicts a simplified magnified schematic of the system of FIG. 7B. Here, the portion of the system 300 includes the chamber interior volume 308, four exhaust ports 398a-398d, and four processing stations that are represented by boxes 319a-319d. FIG. 8B depicts the system 300 during the one or more other operations, such as cleaning operations with the valve 362 in an open position and ballast gas not flowing through the gas injectors 315a and 315b. Cleaning plasma (illustrated by dashed arrows) is seen flowing through the chamber interior and into the foreline 302, and through the RPS interface 326 into the foreline outlet conduit 305.

In some embodiments, the system may include features configured to detect pressure in the chamber interior and/or foreline, and to control the ballast gas flow into the foreline to control, including adjusting and maintaining, the pressure in the chamber interior. This may include one or more pressure sensors positioned in the chamber interior, the foreline, or both, upstream of the gas injectors and connected to a controller. The controller may be configured to receive the signals from the one or more pressure sensors and cause gas to flow into the foreline through the gas injectors to affect the pressure in the foreline and upstream of the foreline to the chamber interior. For example, system 300 of FIG. 8A has one pressure sensor 321 positioned in the interior volume 308 of the chamber 306 that is communicatively connected to a controller 386. The pressure sensor 321 detects pressure in the chamber interior volume 308 and transmits those signals to the controller 386 which receives those signals. The controller 386 is configured to control, based on the received pressure signals, the ballast gas flow from the ballast gas source 317 and to the gas injectors 315a and 315b to control the pressure in the foreline 302 and upstream in the chamber interior volume 308. In some embodiments, the controller 386 may use proportional-integral-derivative (PID) control to control the ballast gas flow based, at least in part, on the detected pressure from the pressure sensor 321. In some instances, the controller may determine the ballast gas flow rate through the gas injectors for achieving a desired pressure result at or near the pressure sensor. In some embodiments, this may type of control may be considered upstream pressure control. In some implementations, the controller may be an upstream pressure controller.

In some implementations, the system 300 may have a flow controller 333 fluidically connected to the gas injectors 315a and 315b, and connected to the pressure sensor 321. The flow controller 333 is configured to control the flow of ballast gas to the gas injectors 315a and 315b based, at least in part, on the detected pressure by the pressure sensor 321. The flow controller 333 may include some of the functionality of controller 386 described above. For example, the flow controller 333 may use PID control to control the ballast gas flow based, at least in part, on the detected pressure from the pressure sensor 321. In some instances, the flow controller 333 may determine the ballast gas flow rate through the gas injectors for achieving the desired pressure result at or near the pressure sensor. In some embodiments, this may type of control may be considered upstream pressure control. In some implementations, the flow controller 333 may be an upstream pressure controller.

In some embodiments, the orifice size in the valve may be configured to provide produce a pressure in the foreline that is less than, but close to the pressure in the chamber interior during the one or more processing operations. This closeness may be, for example, 5%, 10%, or 20% of the desired chamber interior pressure during the operations. During the processing operations, without any ballast gas flow and while the valve is in the closed position, the orifice may therefore cause the foreline to have a first pressure that is less than the pressure in the chamber interior. The additional ballast gas into the foreline thereby increases the pressure in the foreline and can therefore increase its pressure above the first pressure and closer or equal to the pressure in the chamber interior. In one example, the chamber interior may have a desired pressure of about 10 Torr during deposition in the chamber and the gas flow through the foreline in order to achieve this same pressure may be 30 SLM. The orifice may be sized to allow less than, but close to, this flow rate, such as 25 SLM. By permitting a flow rate of about 25 SLM through the orifice, the pressure in the foreline is less than, but also close to, the 10 Torr chamber pressure. To produce the desired flow rate through the foreline, and thereby produce the desired pressure in the foreline, the ballast gas can be flowed into the foreline at about 5 SLM to reach a total of 30 SLM and the desired pressure in the foreline. If there are pressure fluctuations in the chamber during the processing operations, the pressure sensor can detect these changes and the ballast gas flow into the foreline can be adjusted so that the desired pressure in the chamber interior can be maintained. For instance, if the chamber pressure drops, then the ballast gas flow can be increased to increase the foreline pressure and the chamber pressure.

As noted herein, some embodiments of the gas injectors are configured to reduce or prevent material deposition in the foreline. The gas injectors may be positioned within the inner bore of a foreline conduit, such as the linear sections depicts in FIGS. 1A-1C and 7A-8B, for instance. In some implementations, the gas injector as an outlet that may be centered, or substantially centered, within the conduit. This centered placement can reduce unwanted disturbances of the gas flow around the gas injector and provide for more uniform conditions around the gas injector. Disturbances around and downstream of the gas injector can be unwanted because these disturbances increase the shear forces and turbulence of the gas flow which can cause the constituents and gases to combine, e.g., a nucleating reaction, and form unwanted material and byproducts that can be deposited on the foreline and valves therein (e.g., valves 162 and 362). These disturbances caused by the gas injector can be reduced in various ways, such as configuring the diameter of the injector large enough to diffuse the ballast gas flow, or having a muffler at the end of the injector that also may diffuse the gas flow.

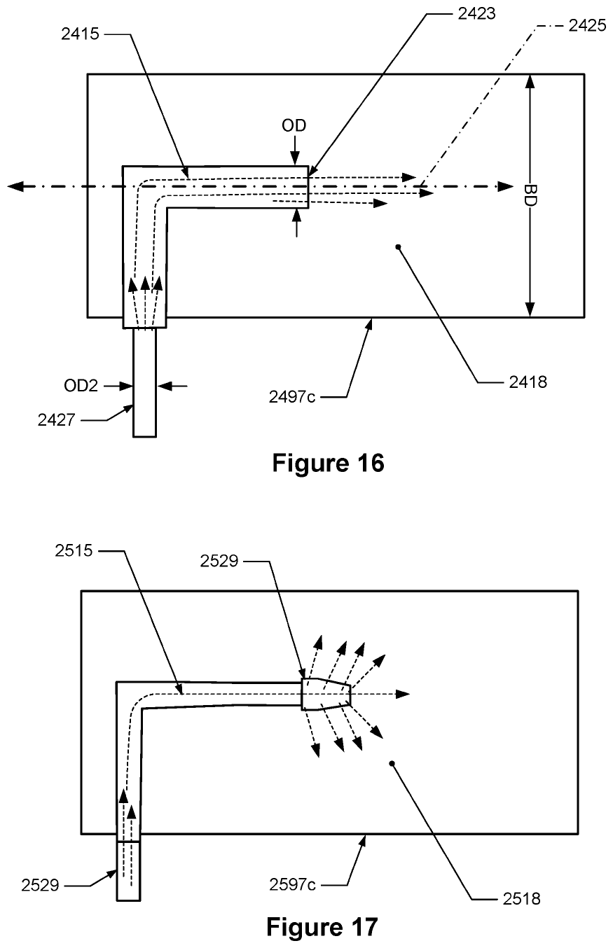

FIG. 16 depicts a cross-sectional side view of a portion of the foreline with a gas injector. This gas injector 2415 is positioned in the interior of the conduit 2497c of a foreline which may be any of the conduits of the foreline networks of FIGS. 1A-1C and 7A-8B. The gas injector 2415 has an outlet 2423 that is positioned in the interior 2418 of the conduit 2497c. The ballast gas flowing through the gas injector 2415 and into the conduit 2497c is represented as dashed arrows. In some instances, the center of the outlet 2423 is in the center region of the conduit 2497c and in some such instances, the center of the outlet 2423 is colinear, or substantially colinear (e.g., within 1%, 5% or 10% of colinear), with the center axis 2425 of the conduit 2497c as illustrated. The outlet 2423 may also have a circular cross-sectional area which can advantageously provide uniform flow of the ballast gas into the conduit 2497c, in some implementations.

Having the diameter of the gas injector and its outlet outer diameter OD sized too small relative to the bore diameter BD of the conduit 2497c can cause unwanted turbulence in the conduit 2497c. In some implementations, having the outer diameter of the gas injector outlet 2423 sized two to six times, two to five times, three to five times, and/or three to six times less than the bore diameter BD of the conduit 2497c advantageously reduces unwanted gas turbulence. Further, the gas injector 2415 may act as a gas expander that allows gas to expand from a delivery line having a smaller diameter. In FIG. 16, the delivery line 2427 from the ballast gas source (not shown) has a second outer diameter OD2 that is smaller than the outer diameter OD of gas injector 2415. This size differential allows the ballast gas to expand and diffuse so that it can enter the interior 2418 of the conduit 2497c with less turbulence.

FIG. 17 depicts a cross-sectional side view of a portion of the foreline with another gas injector. As with the gas injector of FIG. 16, this gas injector 2515 is positioned in the interior of the conduit 2597c of a foreline which may be any of the conduits of the foreline networks of FIGS. 1A-1C and 7A-8B. The gas injector 2515 has an outlet having a muffler 2529 that is positioned in the interior 2518 of the conduit 2597c. The ballast gas flowing through the gas injector 2515 and into the conduit 2597c is represented as dashed arrows. In some instances, the center of the muffler 2529 is in the center region of the conduit 2597 and in some such instances, the center of the muffler 2529 is colinear, or substantially colinear (e.g., within 1%, 5% or 10% of colinear), with the center axis of the conduit 2597c. As illustrated, the muffler 2529 causes the ballast gas to flow radially outwards in various directions to disperse the ballast gas in the conduit interior 2518 which can reduce and prevent unwanted turbulence and deposition therein. The muffler 2529 may be a type of structure that chokes and spreads the flow of the ballast gas into the conduit. This can include a structure with a porous housing, such as a muffler made of sintered metal. In some implementations, the muffler may be considered a pneumatic exhaust muffler.

As noted, the flow of ballast gas into the foreline through the gas injectors can control the pressure in the chamber interior. In some embodiments, flowing this ballast gas while the valve with the orifice is in the closed position during the one or more processing operations, e.g., depositing material on substrates in the multi-station chamber, can result in maintaining the pressure in the chamber interior within a particular pressure range. This range can be from about 7 Torr to about 11 Torr, from about 14 Torr to about 18 Torr, or from about 16 Torr to about 20 Torr.

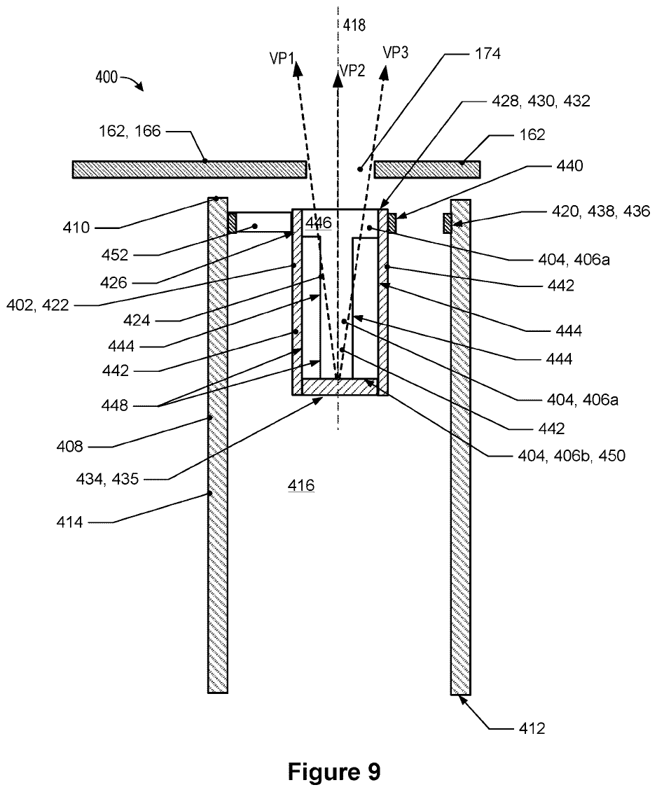

Additional or alternative features of the systems will now be discussed. In some implementations, a foreline anti-fouling assembly may be implemented in a foreline to help trap potential undesirable byproducts, e.g., that may make it past the pendulum valve 162. Referring to FIGS. 9-15, an implementation of a foreline anti-fouling assembly 400 (“assembly”) is provided for the foreline 102 of the semiconductor processing system 100 of FIG. 1C. FIG. 9 depicts a cross-sectional view of an example foreline anti-fouling assembly for foreline of FIG. 1C, as taken along a longitudinal axis of the catcher. The assembly 400 is configured to initiate deposition of material from the one or more process gases flowing through the foreline 102 during the one or more semiconductor processing operations and further configured to retain the deposited material and prevent the deposited material from traveling through the foreline 102 downstream of the assembly 400 during the one or more semiconductor processing operations and/or the foreline cleaning operations. As described in detail above in connection with the description for FIGS. 4-6, the orifice 174 in the gate 166 of the valve 162 may cause a large portion of the process gases to flow through the inner core space of the foreline interior 118 spaced radially inward from the foreline wall 116 and minimize flow interruption by maintaining flow direction and flow rate within the inner core space.

The flow of process gases through the orifice 174 significantly decreases the amount of gases flowing along the tortuous path around the outer edge region 168 of the gate 166 and thus decreases fouling at or near the outer edge region 168. The decreased fouling at or near the outer edge region 168 may in turn prevent the gate 166 from seizing, decrease the frequency of preventative maintenance of the foreline 102, and conserve uptime and corresponding throughput of the semiconductor processing system 100. However, because the orifice 174 maintains flow direction and flow rate within the inner core space of the foreline interior 118 spaced radially inward from the foreline wall 116, the process gases may impinge directly upon a region of the foreline wall 116 that is spaced farther downstream from the gate 166. This region may be difficult to access and/or clean, and in such regions, the material may foul and/or damage other components (e.g., the pump of the exhaust system 122), and thus diminish the performance of those components and/or the entire semiconductor processing system 100. As described in detail below, the semiconductor processing system 100 may include the assembly 400 having a catcher 402 (e.g., a trap, a strainer, etc.) configured to cause material from the one or more process gases to be deposited on one or more accumulation surfaces 404 and to retain that material (e.g., material that becomes dislodged from a surface of the catcher 402) so that the material does not travel through the foreline 102 during the one or more semiconductor processing operations and/or a foreline cleaning operation. During the foreline cleaning operation (e.g., after a predetermined number of batches of semiconductors have been produced, such as 30 batches), a plasma source (e.g., the RPS 128 of FIG. 1) may be caused to flow plasma into the foreline 102 and through the assembly 400 to volatilize the material deposited and stored within the catcher 402. The catcher 402 is further configured to provide conductance through the foreline 102 within a predetermined penalty (e.g., within approximately 20% of the original conductance of the foreline 102 without the catcher 402 in it and before any material from the process gases is deposited on the catcher 402). As material gradually accumulates on the catcher 402 during the one or more semiconductor processing operations, the conductance through the catcher 402 may decrease by a corresponding amount. The catcher 402 is configured to be cleaned within a maximum cleaning time, such as 20-30 minutes, to remove an amount of material associated with an amount of process gases used to produce a predetermined number of batches of semiconductors, such as 30 batches. The foreline cleaning operation, during which the catcher may be cleaned, may be performed during planned maintenance downtime, sequentially before or after a chamber cleaning operation. However, in other implementations, the foreline cleaning operation and the chamber cleaning operation may be performed simultaneously (e.g., when the semiconductor processing system 100 has sufficient plasma resources and corresponding hardware to supply the required amounts of plasma to the processing chamber 106 and the assembly 400, simultaneously). In still other implementations (e.g., where planned downtime is reduced and output is increased relative the above the implementation), the foreline cleaning operation may be performed simultaneously with during one or more semiconductor processing operations. In yet other implementations, the catcher 402 may cause the flow of one or more process gases to be deflected onto a foreline wall (e.g., a foreline segment 408 as discussed below), which may be cleaned during the foreline cleaning operation.

In this implementation, the assembly 400 includes a foreline segment 408 (e.g., a flanged tube or a spool-piece separate from the foreline 102) configured to integrate the catcher 402 in the foreline 102 and receive the flow of the one or more process gases from the interior volume 108 of the processing chamber 106. The foreline segment 408 has an inlet end 410 configured to fluidically connect with a first portion of the foreline 102 fluidically connected with the interior volume 108 of the processing chamber 106. The foreline segment 408 further includes an outlet end 412 configured to fluidically connect with a second portion of the foreline 102 fluidically connected with the exhaust system 122. The foreline segment 408 has a segment wall 414 defining a flow path 416 fluidically interposed between the inlet end 410 and the outlet end 412. The flow path 416 extends along a longitudinal axis 418 and has a segment cross-sectional area A coaxial with the longitudinal axis 418. The assembly 400 further includes one or more support structures 420 configured to attach the catcher 402 to the foreline segment 408 (e.g., prior to the inlet end 410 and the outlet end 412 of the foreline segment 408 being fluidically connected with the first portion and the second portion, respectively, of the foreline 102). Alternatively, the foreline segment 408 may be an integral portion of the foreline 102, and the catcher 402 may be inserted into the foreline 102 via a removable access panel of the foreline 102 and coupled directly to the foreline wall 116.

In this implementation, the assembly 400 further includes a valve 162 (e.g., the pendulum valve 162 of FIGS. 4-6). To avoid undue repetition, the elements of the pendulum valve 162 in the implementation of FIG. 9 that are analogous to elements shown in FIGS. 4-6 are called out with numbers that share the same last two digits as those analogous elements in FIGS. 4-6. Thus, the discussion provided above with respect to the elements of the implementation of FIGS. 4-6 will be understood to be equally applicable to the analogous elements in FIG. 9 unless indicated otherwise. In the interest of conciseness, discussion of these elements that would be redundant of earlier discussion herein of similar elements is not provided, with the understanding that the earlier discussion of such elements is applicable to these similar elements in FIG. 9. In this implementation, the valve 162 includes the gate 166 with the orifice 174 configured to cause a large portion of the process gases to flow through the inner core space of the foreline interior 118 spaced radially inward from the foreline wall 116 and minimize flow interruption by maintaining flow direction and flow rate within the inner core space. The orifice 174 in the gate 166 has a circular shape with a first diameter D1. In other implementations, the orifice 174 may have a non-circular shape (e.g., a polygonal shape, an obround shape, etc.) with a corresponding maximum width. Additional axial features (e.g., slopes or steps) may also be designed into this device in order to achieve the desired flow profile and minimize disturbance causing deposition.

The assembly 400 further includes an apparatus 422 having a catcher 402 configured to be coupled to the foreline segment 408 and further configured to be fluidically interposed between the orifice 174 of the valve 162 and the exhaust system 122 and to remove depositionable material from the process gases. The catcher 402 includes one or more accumulation surfaces 404 configured to be impinged upon by the flow of one or more process gases through the foreline segment 408 and cause material from the one or more process gases to be deposited on the one or more accumulation surfaces 404 during the one or more semiconductor processing operations, and when the catcher 402 is coupled to the foreline segment 408 and the foreline segment 408 is fluidically connected with the foreline 102. The one or more accumulation surfaces 404 are further configured to be impinged upon by plasma, e.g., flowed from the RPS 128 that may be immediately upstream of the valve 162 or flowed from another plasma source, to remove the material from the one or more accumulation surfaces 404 during the foreline cleaning operation, and when the catcher 402 is coupled to the foreline segment 408 and the foreline segment 408 is fluidically connected with the foreline 102.

In this implementation, the catcher is a conduit 424 having a first end portion 426, with the first end portion 426 being an open end 428 having a rim 430 defining an inlet 432. The inlet 432 is configured to receive at least a portion of the flow of the one or more process gases from the orifice 174 in the valve 162 during the one or more semiconductor processing operations. The inlet 432 is further configured to receive the flow of plasma (e.g., originating from the RPS 128 and/or the chamber cleaning plasma source 199, etc.) during the foreline cleaning operation.

Referring to FIG. 9, the inlet 432 in the catcher 402 is offset from the orifice 174 along the longitudinal axis 418 by a maximum distance (e.g., in the range between 0.001 inches to 0.500 inches, etc.) to permit the process gases to flow from the orifice 174 and into the inlet 432. The inlet 432 in the catcher 402 and the orifice 174 in the gate 166 are positioned coaxially when the gate 166 is in the closed position. The inlet 432 of the catcher 402 has a second diameter D2 that is larger than the first diameter D1 of the gate 166, and a ratio of the second diameter of inlet 432 to the first diameter of the orifice 174 is above a minimum ratio (e.g., at least 1.5:1) to further permit the process gases to flow from the orifice 174 and into the inlet 432.

The conduit 424 further includes a second end portion 434 opposite to the first end portion 426. The one or more accumulation surfaces 404 include a first accumulation surface 406a spaced from the second end portion 434 and a second accumulation surface 406b on the second end portion 434. The second end portion 434 may be configured to catch material that may be dislodged from the first accumulation surface 406a, e.g., due to flaking. In one implementation, the second end portion 434 of the conduit 424 is a closed end 435. In other implementations, the second end portion 434 may have one or more openings (e.g., an end wall/second accumulation surface 406b having one or more holes, a screen, a grating, etc. therethrough). The conduit 424 may be made of a steel alloy (e.g., SAE 304 stainless steel), an aluminum alloy, a ceramic material, or other suitable materials.

The assembly 400 may include one or more support structures 420 configured to attach the first end portion 426 of the conduit 424 to the foreline segment 408 (e.g., to hold the inlet 432 of the conduit 424 in a precise location relative to the orifice 174 in the gate 166 where the conduit 424 is positioned coaxially with the orifice 174), and the second end portion 434 of the conduit 424 may be free of the support structures 420 (e.g., to avoid occlusion of the flow path by such support structures 420 and avoid a corresponding decrease in conductance, improve ease of installation, etc.). Other implementations may have the support structures configured to attach the second end portion 434 to the foreline segment 408 with the first end portion 426 being free of the support structures 420, although this may make it more challenging to cause the first end portion 426 to be held in a position that is coaxial with the orifice 174. The support structure 420 may include an outer collar 436 configured to be supported by the segment wall 414 in a lateral direction perpendicular to the longitudinal axis 418. The support structure 420 may further include an annular flange 438 extending radially outward from the outer collar 436 and configured to support the catcher 402 in a longitudinal direction. The annular flange 438 may be held between the inlet end 410 of the foreline segment 408 and the first portion of the foreline 102 when the inlet end 410 and the first portion of the foreline 102 are connected with one another. The support structure 420 may further include an inner collar 440 configured to hold the catcher 402. The support structure 420 may further include one or more radial arms 452 connecting the outer collar 436 with the inner collar 440 and positioning the catcher 402 radially inward from the outer collar 436 (e.g., in a location where the inlet 432 of the catcher 402 is positioned coaxially with the orifice 174 in the gate 166). The first end portion 426 of the conduit 424 may have a first outer diameter and the remainder of the conduit (e.g., at least the second end portion 434) may have a second diameter smaller than the first outer diameter of the first end portion 426 of the conduit 424. The inner collar 440 may have an inner diameter smaller than the first diameter and larger than the second diameter. An upstream side of the inner collar 440 may be configured to engage the first end portion 426 of the conduit 424 and support the catcher 402 in the upstream direction. The inner diameter of the inner collar 440 may be configured to support the catcher in a lateral direction perpendicular to the longitudinal axis 418. In other implementations, the assembly 400 may include any suitable support structure configured to attach any one or more portions of the catcher 402 to the foreline segment 408 or directly to the foreline 102 in implementations where the foreline segment 408 is omitted.

The conduit 424 includes one or more columns 442 (e.g., three columns) extending between the first end portion 426 and the second end portion 434, with the one or more columns 442 being configured to retain the material within the catcher 402 (e.g., material deposited on the one or more accumulation surfaces 404 and later detaching from the one or more accumulation surfaces 404). The conduit 424 further includes one or more outlets 444 configured to provide the catcher 402 with a relatively high conductance (e.g., a conductance much higher than that provided by a porous filter or a mesh filter). In this implementation, the conduit 424 includes three radially-outward facing outlets 444 each defined by the first end portion 426, the second end portion 434, and the corresponding columns 442. For one or more angular positions on the conduit 424, a single outlet 444 exists and extends from the first end portion 426 to the second end portion 434. The middle portions of the columns 442 (i.e., sections spaced from the first end portion 426 and the second end portion 434) are not connected to one another (e.g., by cross members to prevent such cross members from occluding flow through the catcher 402 and avoid a corresponding decrease in conductance through such outlets 444). The second end portion 434 may include an annular flange 438 connected to the columns 442 and configured to retain the material within the catcher 402. The conduit 424 further includes a passage 446 fluidically interposed between the inlet 432 and the one or more outlets 444. The columns 442 and the annular wall 448 are configured to prevent loose material from exiting the passage of the catcher 402 and traveling down the foreline 102.

The catcher 402, without material deposited on it, has a lateral occlusion profile configured to occlude a portion of the flow path 416 in the foreline segment 408. The lateral occlusion profile may correspond with all locations on one or more direct impingement sections 450 of accumulation surfaces 404 on the catcher 402, with each location being within one or more direct lines-of-sight extending from that location and through the orifice 174 in the valve 162 to viewpoints at one or more locations upstream of the valve 162. The one or more direct impingement sections 450 are configured to be directly impinged upon by the one or more process gases to cause the material from the process gases to be deposited onto those direct impingement sections 450. More specifically, the one or more direct impingement sections 450 extend in a direction having a lateral component perpendicular to the longitudinal axis 418 of the catcher 402. For each location in a first set of locations, multiple direct lines of sight exist from that location to corresponding viewpoints external to the catcher 402 and located along an upstream direction of the foreline 102 relative to the catcher 402 and/or the valve 162. Each of these locations in the first set of locations is located on the one or more direct impingement sections 450. The lateral occlusion profile of the catcher is configured to occlude a range between 10% and 50 % of the segment cross-sectional area of the foreline segment 408 when the catcher 402 (i.e., without the material from the process gases deposited on the catcher 402) is installed within the flow path of the foreline segment 408. This range may depend upon a flow profile produced by the orifice 174 and distance from the orifice 174 which creates an angle of view. The lateral occlusion profile is an aggregate cross-sectional area of the lateral components of all of the one or more direct impingement sections 450. In this implementation, each of the columns 442 extend between the first end portion 426 and the second end portion 434 and along a direction that has no lateral component perpendicular to the longitudinal axis 418, and thus the columns 442 do not contribute to the lateral occlusion profile. Put another way, the aggregate cross-sectional area may be the cross-sectional flow area of the foreline 102 without the catcher 402 in the foreline 102 reduced by the cross-sectional flow area of the foreline 102 with the catcher 402 in the foreline 102.

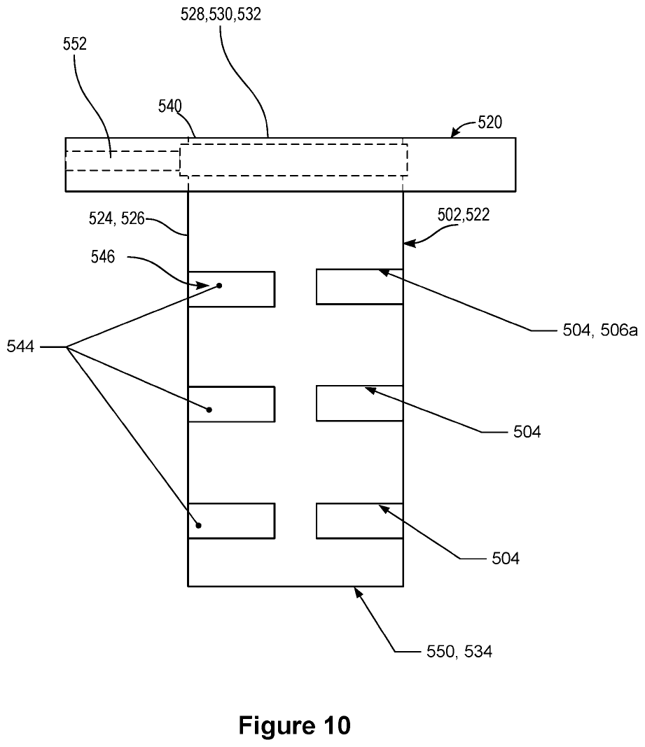

FIG. 10 depicts another implementation of the catcher of FIG. 9. The example catcher 502 of FIG. 10 is somewhat similar to the catcher 402 of FIG. 9. To avoid undue repetition, elements in the implementation of FIG. 10 that are analogous to elements shown in FIG. 9 are called out with numbers that share the same last two digits as those analogous elements in FIG. 9. Thus, the discussion provided above with respect to the elements of the implementation of FIG. 9 will be understood to be equally applicable to the analogous elements in FIG. 10 unless indicated otherwise. In the interest of conciseness, discussion of these elements that would be redundant of earlier discussion herein of similar elements is not provided, with the understanding that the earlier discussion of such elements is applicable to these similar elements in FIG. 10.

While the catcher 402 of FIG. 9 includes a single outlet 444 at a corresponding one or more angular positions of the conduit 424, the catcher 502 may be a cage or strainer including a set of multiple outlets 544 at each corresponding angular position on the wall of the conduit 524. In contrast to the conduit 424 of FIG. 9 having multiple separate columns 442 with middle portions (i.e., sections spaced from the first end portion 426 and the second end portion 434) not connected to one another, the conduit 524 includes a lateral wall (also labeled 524 in FIG. 10) extending between the first end portion 526 and the second end portion 534. At one or more angular positions on the wall of the conduit 524, the lateral wall 542 includes a corresponding set of multiple outlets 544. The lateral wall 542 defines the passage 546 along the longitudinal axis, with the passage 546 fluidically interposed between the inlet 532 and the one or more outlets 544. In some embodiments, the catcher 502 may be oriented similar to the catcher of FIG. 9, with the open end of the first end portion 526 adjacent to the gate 166. In other embodiments, the second end portion 534 of the catcher 534 may be open and positioned proximate to the gate 166 while the first end portion 526 may be closed and positioned farther from the gate than the second end portion 534.

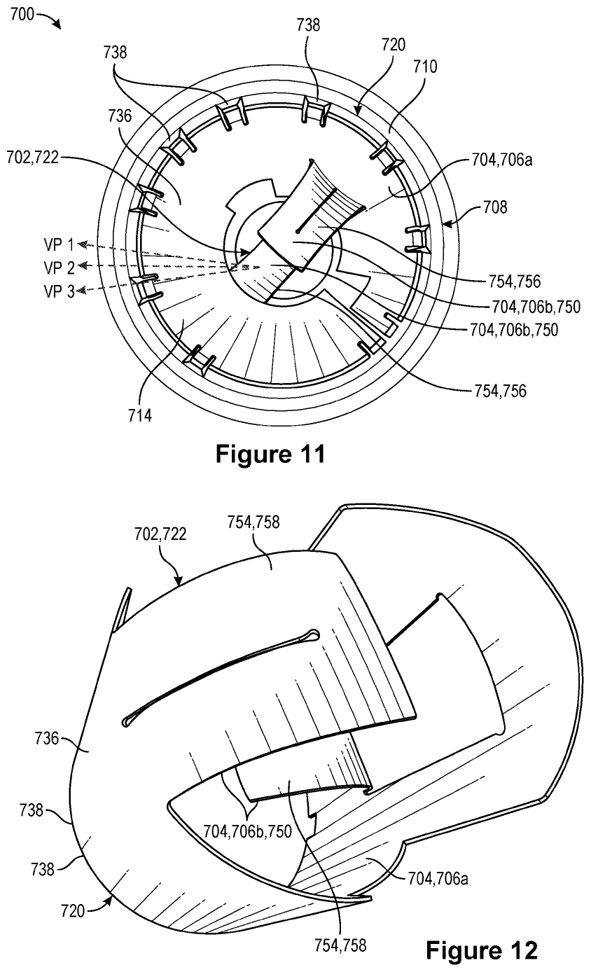

FIGS. 11 and 12 depict another example foreline segment 708 and catcher 702 that are analogous to the foreline segment 408 and catcher 402 of FIG. 9. FIG. 11 depicts still another implementation of the catcher of FIG. 9. FIG. 12 depicts a bottom perspective view of the panels of FIG. 11. To avoid undue repetition, elements in the implementation of FIGS. 11 and 12 that are analogous to elements shown in FIG. 9 are called out with numbers that share the same last two digits as those analogous elements in FIG. 9. Thus, the discussion provided above with respect to the elements of the implementation of FIG. 9 will be understood to be equally applicable to the analogous elements in FIGS. 11 and 12 unless indicated otherwise. In the interest of conciseness, discussion of these elements that would be redundant of earlier discussion herein of similar elements is not provided, with the understanding that the earlier discussion of such elements is applicable to these similar elements in FIGS. 11 and 12.

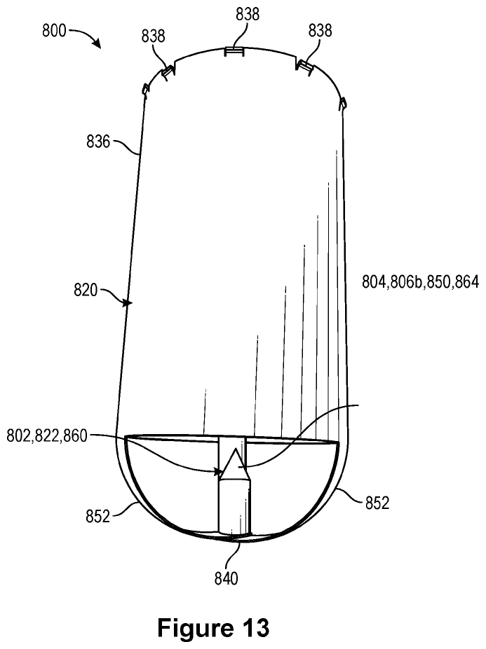

While the catcher 402 of FIG. 9 is the conduit 424 having the inlet 432 and one or more outlets 444, the catcher 702 of FIGS. 11 and 12 includes a plurality of panels 754 having the accumulation surface 704 with the direct impingement sections 750. Multiple direct lines-of-sight exist from a first location of a set of locations on each direct impingement section 750 to external viewpoints located in an upstream location in the foreline 102 (FIG. 1). The accumulation surfaces 704 may include one or more convex surface portions 756 and/or one or more concave surface portions 758. In other implementations, the accumulation surface may have one or more planar surface portions, As shown in FIG. 13, the support structure 720 may be the outer collar 736 in connection between each panel 754 and the foreline segment 408 (FIG. 9).

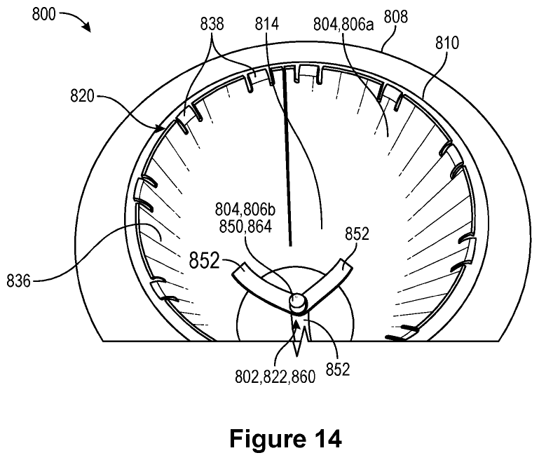

FIGS. 13 and 14 depict another example foreline segment 808 and catcher 802 that is analogous to the foreline segment 408 and catcher 402 of FIG. 9. FIG. 13 depicts a side view of another implementation of the foreline anti-fouling assembly of FIG. 9 and FIG. 14 depicts a perspective end view of the catcher of FIG. 13. To avoid undue repetition, elements in the implementation of FIGS. 13 and 14 that are analogous to elements shown in FIG. 9 are called out with numbers that share the same last two digits as those analogous elements in FIG. 9. Thus, the discussion provided above with respect to the elements of the implementation of FIG. 9 will be understood to be equally applicable to the analogous elements in FIGS. 13 and 14 unless indicated otherwise. In the interest of conciseness, discussion of these elements that would be redundant of earlier discussion herein of similar elements is not provided, with the understanding that the earlier discussion of such elements is applicable to these similar elements in FIGS. 13 and 14.

While the catcher 402 of FIG. 9 is the conduit 424 with the inlet 432 and one or more outlets 444, the catcher 802 of FIGS. 13 and 14 is a post 860 having a shaft terminating at a tip 864 (e.g., a tapered tip, such as a conical tip), and one or both of the shaft and the tip 864 have the one or more accumulation surfaces 804 that cause material from the flow of process gases to be deposited on those accumulation surfaces 804. In contrast to the support structure 420 of FIG. 9 having the outer collar 436 (e.g., the annular band), the inner collar 440, and the one or more radial arms 452, the support structure 820 of FIGS. 13 and 14 have the outer collar 836 (e.g., a tube), a support platform 840 configured to support the post 860, and one or more radial arms 852 connecting the outer collar 836 with the support platform 840 and positioning the post 860 radially inward from the outer collar 436 (e.g., in a location where the shaft of the post 860 is positioned coaxially with the orifice 174 in the gate 166 of FIG. 9).

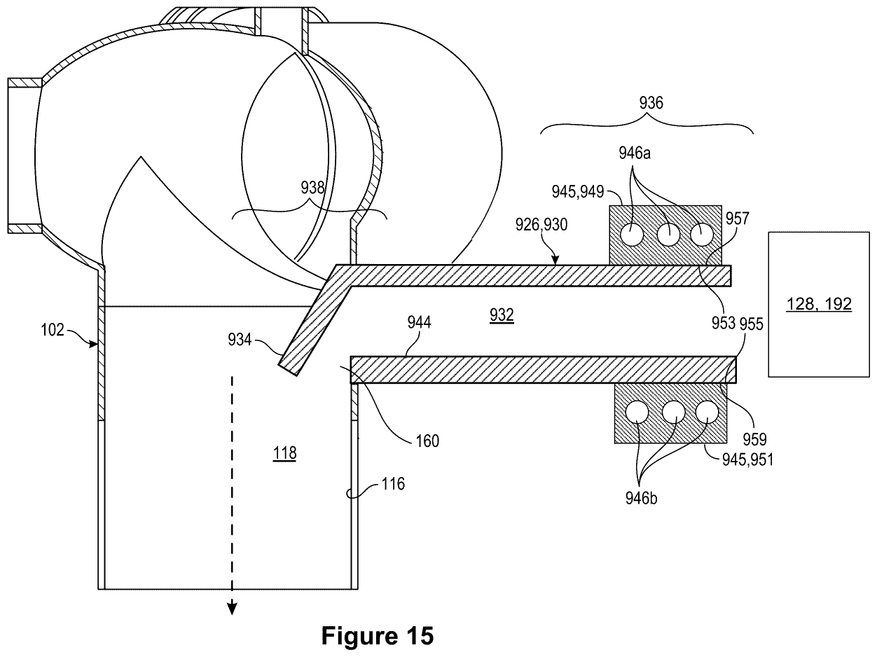

FIG. 15 depicts another example RPS interface 926 that is somewhat similar to the RPS interface 126 of FIGS. 2 and 3. FIG. 15 depicts an enlarged cutaway view of Region 1 of the semiconductor processing system of FIG. 1C. To avoid undue repetition, elements in the implementation of FIG. 15 that are analogous to elements shown in FIGS. 2 and 3 are called out with numbers that share the same last two digits as those analogous elements in FIGS. 2 and 3. Thus, the discussion provided above with respect to the elements of the implementation of FIGS. 2 and 3 will be understood to be equally applicable to the analogous elements in FIG. 15 unless indicated otherwise. In the interest of conciseness, discussion of these elements that would be redundant of earlier discussion herein of similar elements is not provided, with the understanding that the earlier discussion of such elements is applicable to these similar elements in FIG. 15.

While the RPS interface 126 of FIG. 2 includes the nozzle 130 with one or more coolant passages 146 located in the nozzle wall 144, the RPS interface 926 of FIG. 15 includes one or more coolant passages 946 located external to the nozzle 930 and/or the foreline 102. The RPS interface 926 includes one or more heat sinks 945 located external to the nozzle wall 944 and attached to a second surface of the nozzle wall 944 facing radially outward relative to the central axis of the plasma passage 932.

As shown in FIG. 15, the one or more coolant passages 946a, 946b are located in the heat sinks 945 and define one or more coolant flow paths leading from an inlet port in a corresponding heat sinks 945 to an outlet port in the corresponding heat sinks 945. In this implementation, the one or more heat sinks 945 are attached to the first end portion 936 of the nozzle wall 944 (e.g., adjacent to the remote plasma source 128, etc.). In other implementations, the one or more heat sinks 945 may be attached to other portions of the nozzle wall 944 (e.g., the second end portion 938 adjacent to the foreline 102).

In this implementation, the one or more heat sinks 945 may include a first heat sink 949 (e.g., a first block) and a second heat sink 951 (e.g., a second block) each made of a material (e.g., aluminum, copper, nickel, etc.) having a coefficient of thermal conductivity within a predetermined range (e.g., a range between 100 and 500 W/m*K). The first heat sink 949 and the second heat sink 951 may each have one or more interface surfaces (e.g., concave surfaces 953, 955) configured to contact and receive heat from a corresponding one of two portions of the nozzle wall 944 (e.g., convex surfaces 957, 959). The first heat sink 949 and the second heat sink 951 may be clamped to the nozzle 930 by one or more fasteners (e.g., threaded fasteners, etc.). The first heat sink 949 may have a first plurality of the coolant passages 946a (e.g., seven coolant passages 946a) arranged parallel to one another and fluidically interposed between a first inlet port and a first outlet port. The first inlet port of the first heat sink 949 may be fluidically connected to a coolant supply line (not shown). The second heat sink 951 may have a second plurality of the coolant passages 946b (e.g., seven coolant passages 946b) arranged parallel to one another and fluidically interposed between a second inlet port and a second outlet port. The second outlet port of the second heat sink 951 may be fluidically connected with a coolant return line (not shown). A connector line may be fluidically interposed between the first outlet port of the first heat sink 949 and the second inlet port of the second heat sink 951. In other implementations, the first heat sink 949 and/or the second heat sink 951 may have more or fewer than seven coolant passages (e.g., a single serpentine coolant passage in one or more of the corresponding heat sinks, etc.), and the RPS interface 926 may include more or fewer than the two heat sinks 949, 951.

In some implementations, the controller 186 is part of the semiconductor processing system 100, which may be part of or include the above-described examples. As described above, the controller 186 may be configured to control the valves 182 of the gas distribution system 180 to cause the one or more process gases to be flowed into the processing chamber 106 to adjust the chamber pressure associated with all process gases flowing through the orifice 174 when the gate 166 is in the first position. The controller 186 may be further configured to control the valves 182 of the gas distribution system 180 to not cause the one or more process gases to be flowed into the processing chamber 106 during the foreline cleaning operation. In implementations where the semiconductor processing system 100 further includes the remote plasma source 128 and the foreline plasma valve 188 fluidically interposed between the remote plasma source 128 and the RPS interface 126 of the foreline 102, the controller 186 may be further configured to control the remote plasma source 128 and the foreline plasma valve 188 to cause the plasma from the remote plasma source 128 to be flowed into the foreline 102 and/or through the catcher 402 during the foreline cleaning operation.

The controller 186 may be further configured to control the foreline plasma valve 188 to block the one or more process gases from flowing through the RPS interface 126 and into the remote plasma source 128 so as to prevent material from the process gases from being deposited in the RPS interface 126. The semiconductor processing system 100 may further include the chamber cleaning plasma source 199 (separate from the foreline cleaning plasma source 192) and a chamber plasma valve 198 fluidically interposed between the chamber cleaning plasma source 199 and the interior volume 108 of the processing chamber 106. The controller 186 may be further configured to control the chamber cleaning plasma source 199 and the chamber plasma valve 198 to cause the plasma from the chamber cleaning plasma source 199 to be flowed into the interior volume 108 of the processing chamber 106 during the chamber cleaning process.

The controller 186 may be further configured to control the chamber plasma valve 198 to stop the flow of plasma into the interior volume 108 of the processing chamber 106 to avoid unnecessarily subjecting the chamber surfaces to additional plasma exposure (e.g., when the chamber surfaces have been cleaned and the foreline plasma valve 188 continuous to flow plasma into the foreline 102 and downstream to the exhaust interface). Such systems with these example controllers may include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein that may cause fouling of the foreline 102 and/or the valve 162, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

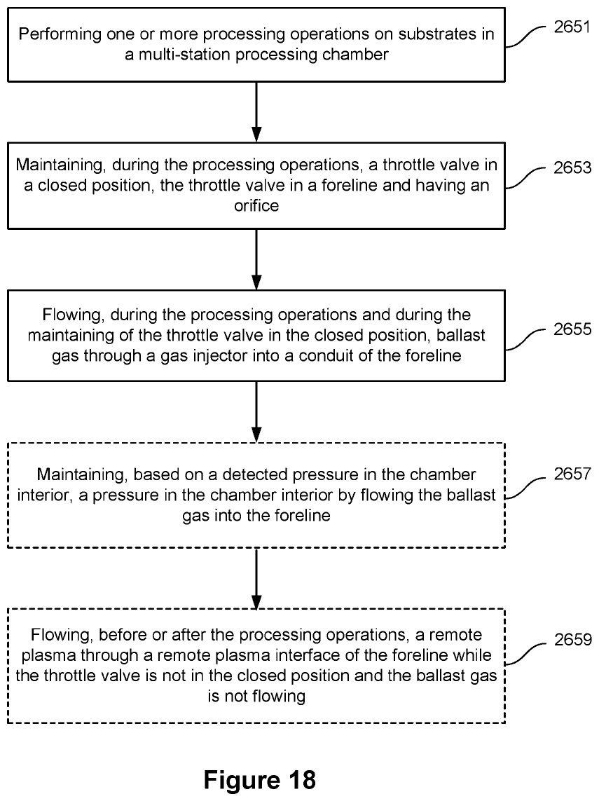

Various techniques may be used with the systems provided herein. FIG. 18 depicts one example technique according to various embodiments. In block 2651, one or more processing operations, such as depositing material, are performed on at least one substrate in a processing chamber. This may include performing one or more processing operations on substrates in a multi-station chamber, such as chambers 106 and 306 provided herein. In block 2653, during the processing operations of block 2651, the valve in the foreline, such as throttle valve or pendulum valve 162 and 362 provided herein, may be in the closed position as illustrated in, for example, FIGS. 4, 7A, and 8A. During the processing operations of block 2651, the gases flowing through the foreline and the throttle valve 162 and 362, such gases may flow only through the orifice and around other features of the gate. Also during the processing operations of block 2651, in some implementations, the ballast gas is flowed into the foreline through the ballast gas injectors, such as the gas injectors 115, 315a, and 315b as indicated by block 2655.

In some embodiments, during this ballast gas flowing, the pressure of a portion of the foreline network, such as the areas upstream of the injectors, may be maintained within a desired pressure range. For example, referring to FIG. 8A, flowing ballast gas through the gas injector 315a can result in the pressure upstream of gas injector 315a, such as segments 396c, 396b, and 396a, as well as the interior volume 308 of the chamber can be maintained at a pressure within a pressure range. In some instances, this pressure range may be within a particular threshold of the desired pressure of the chamber interior volume 308 during the processing operations. For instance, the pressure range may be within at least 0.1%, 0.5%, 1%, 5%, 10%, or 25% of the desired pressure in the chamber. As also provided herein, some techniques may detect a pressure upstream of the gas injector and the flow of the ballast gas may be based, at least in part, on this detected pressure. This can include detecting the pressure with pressure sensor 321 of FIG. 8A and using upstream flow control and/or PID control to flow of ballast gas into the foreline 302 and maintain the desired pressure in the foreline 302 and/or chamber interior volume 308. This maintaining of the chamber interior pressure and detecting the pressure is represented by optional block 2657 in FIG. 18.

In some embodiments, a remote plasma may be flowed into the foreline through the RPS interface as provided herein to clean aspects of the foreline. This is represented by optional block 2659 of FIG. 18. During this flowing of the remote plasma, the ballast gas is not flowed into the foreline and the throttle valve is not in the closed position. The throttle valve operates to control the flow and/or pressure within the foreline and chamber interior. This block 2659 may be considered performing one or more other operations in the chamber which may be a cleaning operation. Further, in some implementations, this remote plasma flowing may occur during a cleaning operation of the processing chamber where a cleaning plasma is flowed within the chamber interior.

The controller may be configured to cause the various techniques to be performed which includes causing various functions to occur in the systems provided herein. In some implementations, this may include causing the one or more processors to cause ballast gas to flow through the gas injector and into the foreline network during one or more processing operations, as described herein. This may also include receiving signals from the pressure sensor in the chamber interior and causing the gas to flow based, at least in part, on the pressure detected by the pressure sensor. This flowing is able to maintain a portion of the foreline, such as the foreline network, within a pressure range. The instructions can further case the throttle valve to be in a closed position while the gas is flowed through the gas injector and while the one or more processing operations are performed in the chamber. During other operations, like pre-and post-processing steps such as cleaning, the instructions may cause the throttle valve to control the pressure within the interior volume during such other operations. The controller may also cause the remote plasma to be generated and flowed to the RPS interface and into the foreline.

Some other embodiments are provided herein that utilize a bypass conduit. In some other embodiments, to mitigate sudden expansion of effluent within a foreline, the foreline may comprise a small diameter (e.g., lower conductance) bypass conduit that branches from greater-diameter (e.g., greater conductance) foreline outlet conduit. The bypass conduit may extend from a branchpoint and rejoins foreline outlet conduit at a reentry point on foreline outlet conduit downstream from branchpoint. The bypass conduit may have a first diameter that is less than a second diameter of foreline outlet conduit. For example, a first diameter is half of second diameter or less. The bypass conduit may have a first length that is at least same as a second length of foreline.

In some implementations, the bypass conduit mitigates or eliminates clogging of the foreline by directing effluent flow through a higher-pressure flow path rather than through a lower pressure flow path afforded by a greater-diameter foreline outlet conduit. In some implementations, a first valve in foreline may be closed and a second valve in the bypass conduit may be opened to direct effluent into the bypass conduit during normal deposition processes. As many deposition processes are performed at relatively high pressures within a deposition chamber, a gradual pressure reduction of effluent gases transiting through bypass conduit can prevent sudden expansion of effluent gases. In at least one implementation, by mitigating sudden gas expansion, deposition of solid or semi-solid material on conduit surfaces by effluent gases is also mitigated or prevented. In at least one implementation, first diameter and length of bypass conduit may be adjusted to regulate pressure drop of effluent gases to match design criteria of a particular vacuum pumping system.

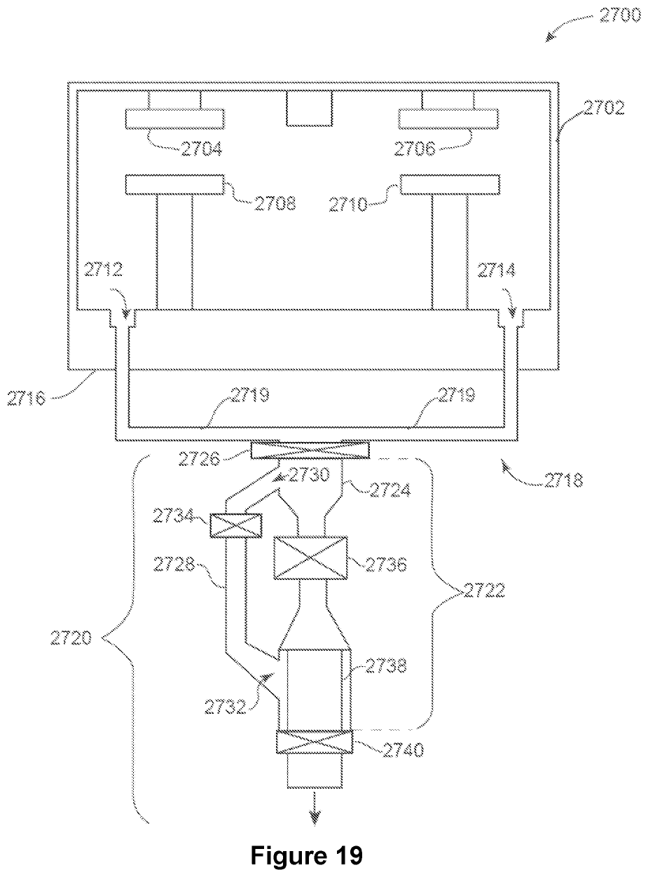

FIG. 19 depicts a cross-sectional view of process tool 2700, according to some implementations. Process tool 2700 comprises a vacuum chamber 2702, also referred to as a process chamber provided above, such as chamber 106 and 306, for example, operable to maintain a high vacuum (e.g., 20 torr or less). The vacuum process chamber may comprise showerheads 2704 and 2706 positioned over pedestals 2708 and 2710, respectively. In some implementations, vacuum chamber 2702 comprises multiple process stations arranged within vacuum chamber 2702. Showerhead 2704 and pedestal 2708 may be allocated to a first process station, while showerhead 2706 and pedestal 2710 may be allocated to a second process station. In some instances, similar to above, vacuum chamber 2702 comprises four process stations, each station comprising a showerhead (e.g., similar or identical to showerhead 2704) and a pedestal (e.g., similar or identical to pedestal 2708). In some embodiments, the vacuum chamber 2702 may a plasma deposition chamber, operable to generate and sustain plasmas at one or more process stations (e.g., plasma sustained between showerhead and pedestal pairs). Plasmas may be ignited by large radio frequency (RF) voltages applied to showerheads 2704 and 2706.

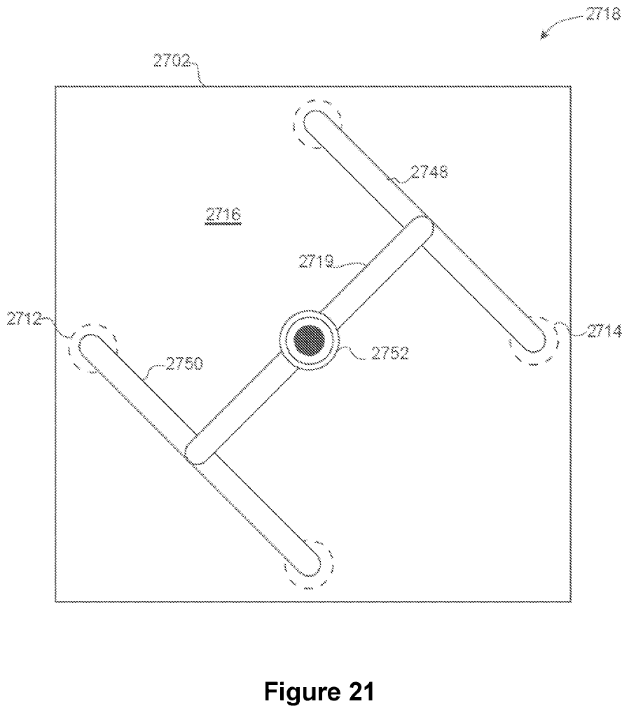

Process gases may be introduced into vacuum chamber 2702 through showerheads 2704 and 2706. Outlet ports 2712 and 2714, which are the same as the exhaust ports referred to herein above, are located on a bottom wall 2716 (or a sidewall) of vacuum chamber 2702. The outlet ports 2712 and 2714 provide an exhaust route for removing process gas effluent from vacuum chamber 2702. The outlet ports 2712 and 2714 are coupled to a foreline having a foreline network 2718. Here, the foreline network 2718 comprises conduit 2719 that is coupled to outlet ports 2712 and 2714. In some implementations, the foreline network 2718 comprises multiple conduits (see FIG. 21).

The foreline also includes foreline outlet conduit 2722 coupled to foreline network 2718. The foreline outlet conduit 2722 comprises expanded section 2724 and the metering valve 2726 is shown between foreline network 2718 and foreline outlet conduit 2722. The metering valve 2726 is operable to be adjustable between fully open to minimally open. The metering valve 2726 can provide a leakage path for process gas effluent to escape into expanded section 2724. The metering valve 2726 may be adjusted to restrict effluent flow to maintain a minimal working pressure within vacuum chamber 2702. In at least one implementation, the metering valve 2726 is a throttle valve, a pendulum valve, a butterfly valve, or a gate valve.

In some embodiments, the vacuum chamber 2702 may be maintained at significantly lower pressures than working pressures employed during deposition operations. To maintain low pressures within vacuum chamber 2702, flow rates of cleaning gas effluent (e.g., nitrogen, argon) may be significantly higher than effluent flow rates during deposition operations. The higher flow rates of clean gases may permit rapid chamber flushing, and maintain lower pressure in vacuum chamber 2702. The metering valve 2726 may be adjusted to be fully open during chamber clean operations to support high effluent flow rate.

As seen in FIG. 19, the bypass conduit 2728 is coupled to foreline outlet conduit 2722 at two places. The bypass conduit 2728 branches from foreline outlet conduit 2722 at branch point 2730. In at least one implementation, branch point 2730 is located on expanded section 2724 and near or within metering valve 2726. The bypass conduit 2728 rejoins foreline outlet conduit 2722 at reentry point 2732 downstream of branch point 2730.

The bypass conduit 2728 provides a region-controlled expansion of effluent gases flowing from metering valve 2726. The bypass conduit 2728 has a significantly smaller volume than expanded section 2724. In at least one implementation, effluent gases may be directed to flow into bypass conduit 2728 by opening of valve 2734 near or within an entrance to bypass conduit 2728, and closing of valve 2736 on foreline outlet conduit 2722. The effluent gases flowing in bypass conduit 2728 may experience a controlled pressure drop after passing out of foreline network 2718 through metering valve 2726, mitigating Joule-Thompson cooling of effluent gases.

In at least one implementation, process gas effluent passing through a narrow opening in metering valve 2726 may rapidly expand upon entering expanded section 2724. A sudden drop in gas pressure may cause an adiabatic expansion of effluent gases, resulting in a rapid drop in gas temperature (Joule-Thompson effect). When effluent gas temperatures drop below condensation temperatures of deposition precursors, solid and semisolid materials may be caused to condense on interior surfaces of foreline outlet conduit 2722. Solid and semisolid material may build up on interior surfaces of foreline outlet conduit 2722 over several process operations, formed by condensed (and polymerized) deposition compounds (e.g., deposition precursors) entrained in effluent. Such contamination can clog foreline outlet conduit 2722, necessitating dismantling of vacuum pumping system to remove clog and clean foreline outlet conduit 2722.

In some embodiments, bypass conduit 2728 provides an alternate flow path to foreline outlet conduit 2722. In FIG. 19, the bypass conduit 2728 branches from foreline outlet conduit 2722 at branch point 2730 and rejoins foreline outlet conduit 2722 at reentry point 2732. Due to smaller expansion volume than expanded section 2724, bypass conduit 2728 can mitigate sudden pressure drops of effluent gases flowing through metering valve 2726. In at least one implementation, flow resistance of bypass conduit 2728 may be engineered to provide sufficient back pressure upstream of metering valve 2726 to allow deposition processes to proceed in vacuum chamber 2702 without restricting flow through metering valve 2726, as described above. In at least one implementation, pressure drop of effluent gases flowing within bypass conduit 2728 may be gradual. In at least one implementation, effluent gas pressure may drop monotonically over length of bypass conduit 2728. In at least one implementation, temperature of effluent gases can remain above condensation temperatures, thereby mitigating condensation of effluent components. The effluent gasses may be directed to flow into bypass conduit 2728 by opening of valve 2734 on bypass conduit 2728 and closure of valve 2736 on foreline outlet conduit 2722.

In at least one implementation, a filter or filter 2738 may be located in-line with foreline outlet conduit 2722, adjacent to reentry point 2732, to capture condensed particulates that may be entrained within effluent flow passing through bypass conduit 2728. The foreline outlet conduit 2722 may terminate at valve 2740. Valve 2740 can isolate foreline outlet conduit 2722 from vacuum pumps that may be coupled to foreline outlet conduit 2722 through valve 2740 (indicated by down-pointing arrow).

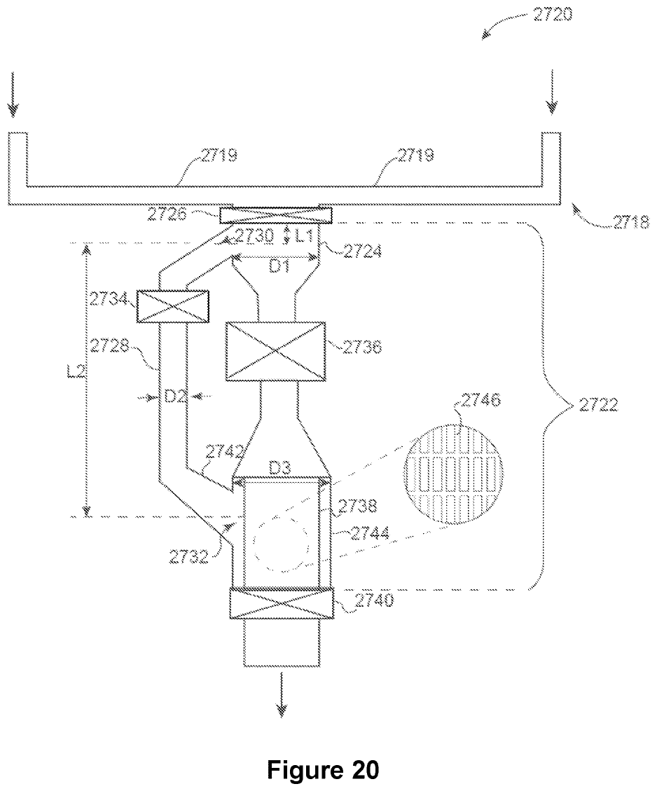

FIG. 20 depicts a cross-sectional view of vacuum pumping system 2720, according to some implementations. While many components of vacuum pumping system 2720 have already been introduced in FIG. 19, further details are described below. The branch point 2730 may be located a distance L1 downstream from metering valve 2726 and the reentry point 2732 may be located a distance L2 downstream of branch point 2730. In some instances, distance L2 may also be approximately a length of bypass conduit 2728. Bypass conduit 2728 has a diameter D1 and in some implementations, diameter D1 may be less than diameter D2 of expanded section 2724 to support a low conductance flow path for process effluent. The bypass conduit may be a low conductance conduit to enable low effluent flow and higher working pressures within vacuum chamber 2702.

In at least one implementation, diameter D2 of expanded section 2724 may be approximately 4 inches (approximately 10 cm). Diameter D2 may be chosen to create a high conductance, high flow path to allow cleaning gases and effluent to sweep through process chamber 2702 rapidly. The diameter D1 of bypass conduit 2728 may be approximately 2 inches (approximately 5 cm) or less, in some embodiments. In at least one implementation, bypass conduit 2728 may be engineered to enable gradual pressure drop of effluent gases to avoid rapid pressure drop of effluent gases, thereby mitigating condensation of precursors on inner walls of foreline outlet conduit 2722. The diameter D1 and length L2 of bypass conduit 2728 may be adjusted to develop a low conductance flow path suitable to produce small pressure gradients along bypass conduit 2728 that may significantly limit pressure drop of effluent gases flowing through bypass conduit 2728 prior to reentering foreline outlet conduit 2722. In at least one implementation, a ballast gas may be introduced near branch point 2730 to maintain working chamber pressure at a preset level. This may be the same or similar ballast gas injection provided above.

In at least one implementation, pressure gradients within bypass conduit 2728 may also be engineered to maintain relatively high working pressures within vacuum chamber 2702 without significantly closing down metering valve 2726 to restrict effluent flow into vacuum pumping system 2720. In some implementations, working pressures within vacuum chamber 2702 may be 5 torr or greater during plasma or non-plasma deposition processes. The bypass conduit 2728 may comprise expanded portion 2742 upstream of reentry point 2732. In at least one implementation, expanded portion 2742 may permit gradual expansion and pressure drop of effluent gases reentering foreline outlet conduit 2722 at reentry point 2732. In at least one implementation, foreline outlet conduit 2722 is a high conductance flow path.

As further shown in FIG. 20, reentry point 2732 opens into lower section 2744 of foreline outlet conduit 2722. The lower section 2744 may have a diameter D3 that is like diameter D2 of expanded section 2724. In at least one implementation, within lower section 2744, effluent expansion may be more rapid than in bypass conduit 2728, but may occur less abruptly than in expanded section 2724. The filter 2738 may be included within lower section 2744 to capture condensed particulate that may be entrained within effluent flow. In some implementations, filter 2738 comprises apertures 2746, shown in inset. The apertures 2746 may have a characteristic diameter of 3 mm or less, where, in other implementations, the characteristic diameter may be a geometric diameter (e.g., circular apertures 2746) or a hydraulic diameter (e.g., rectangular apertures 2746).

FIG. 21 illustrates a plan view of foreline network 2718, in accordance with at least one implementation. This may be similar to the foreline network of FIGS. 8A and 8B. Here, view is of a bottom wall 2716 of vacuum chamber 2702 and vacuum chamber 2702 comprises four process stations. The foreline network 2718 extends over bottom wall 2716 of vacuum chamber 2702 and the foreline network 2718 comprises conduits 2748 and 2750. In at least one implementation, conduits 2748 and 2750 are interconnected by conduit 2719. In at least one implementation, conduits 2748 and 2750 comprise vertical interconnections (e.g., extending in z dimension of figure), coupling conduits 2748 and 2750 to outlet ports (e.g., outlet ports 2712 and 2714, shown as hidden lines).

In at least one implementation, flange 2752 extends over conduit 2719. In at least one implementation, flange 2752 has a greater diameter than conduit 2719. In at least one implementation, flange 2752 may provide a junction to couple expanded section 2724 of foreline outlet conduit 2722, or metering valve 2726 to foreline network 2718.

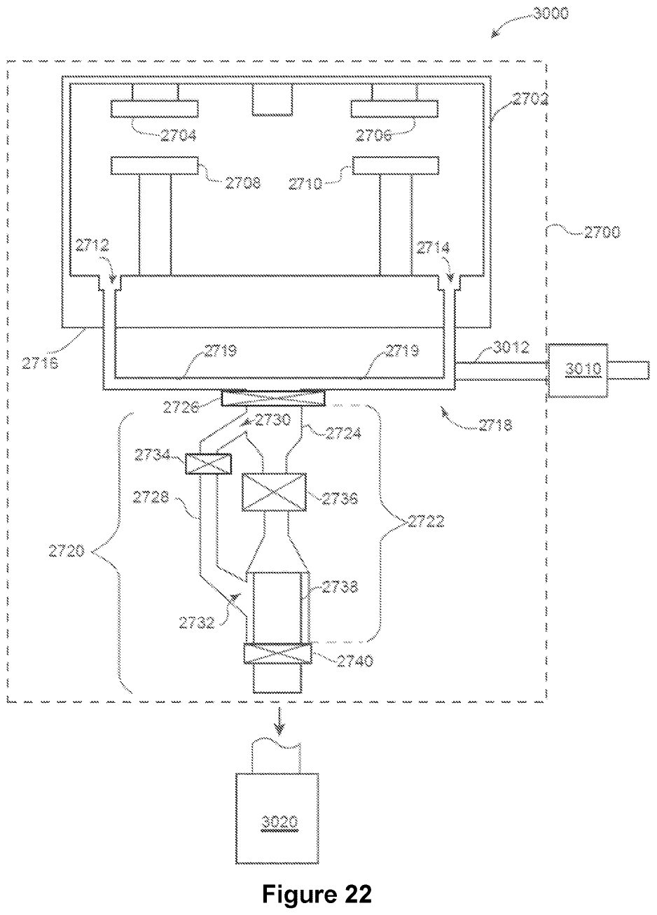

FIG. 22 illustrates a cross-sectional view of process tool system 3000, comprising process tool 2700 (enclosed in dashed box) coupled to mass flow controller 3010 and vacuum pump 3020, in accordance with at least one implementation. The flow controller 3010 is coupled to foreline network 2718 through conduit 3012 and may be coupled to a supply of make-up or ballast gas (e.g., nitrogen, argon) that is introduced into foreline network 2718. The flow controller 3010 may be operable to control flow of make-up or ballast gas to maintain working pressures in vacuum chamber 2702 during deposition processes. In at least one implementation, while able to control pressure drop of effluent gases as described above, bypass conduit 2728 may not be able to sustain working pressures within vacuum chamber 2702. In at least one implementation, flow controller 3010 may be adjusted to flow make-up gas from an external gas supply (not shown) into foreline network 2718 to pressurize conduits 2719 (and conduits 2748 and 2750, FIG. 21), boosting working pressures within vacuum chamber 2702.

The vacuum pump 3020 is shown coupled to foreline outlet conduit 2722 below valve 2740. In at least one implementation, vacuum pump 3020 comprises a diffusion pump or a turbomolecular pump to generate a high vacuum, followed by a roughing pump (not shown).

The valve 2740 is operable to isolate process tool 2700 from vacuum pump 3020. In at least one implementation, valve 2740 is a gate valve and is configured to be closed to isolate vacuum chamber 2702 and vacuum pumping system 2720 when tool maintenance is performed. In at least one implementation, vacuum chamber 2702 may be brought to atmospheric pressure and opened to access process stations. Isolation of both process tool 2700 and vacuum pump 3020 by valve 2740 may enable pumps of pumping system to continue pumping during tool maintenance, saving start-up time (e.g., preconditioning of diffusion pump) when process tool system 3000 is placed back in service.

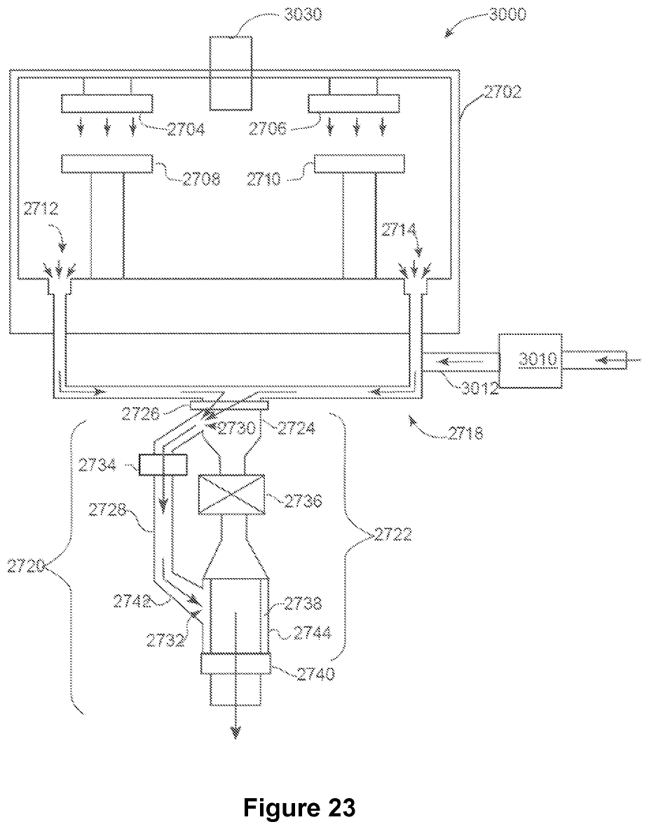

FIG. 23 depicts a cross-sectional view of the process tool system of FIG. 22 undergoing a deposition operation, according to at least one implementation. As shown, chamber 2702 is a multi-station chamber and the deposition operation is performed on both substrates in the chamber 2702. As described herein, in some embodiments, this operation may be etching operations on the substrates in the chamber 2702 while in other embodiments, this operation may be etching at least one substrate while concurrently depositing on another substrate. Process gas is introduced into vacuum chamber 2702 of process tool system 3000 through showerheads 2704 and 2706. Down-pointing arrows below showerheads 2704 and 2706 indicate introduction of process gases into vacuum chamber 2702.

In some implementations, process gases may comprise gas-phase precursor compounds diluted in a carrier gas such as nitrogen or argon. The precursor compounds may be sublimated or vaporized at elevated temperatures from solid or liquid sources. Process gases may be preheated to elevated temperatures prior to entering showerheads 2704 and 2706. In some implementations, vaporized precursors may not condense upon leaving showerheads 2704 and 2706 as process gases may not undergo large changes in pressure when entering vacuum chamber 2702. Plasmas (not shown) may be ignited and sustained between showerhead 2704 and pedestal 2708, and between showerhead 2706 and pedestal 2710. The temperatures within plasmas may be substantially elevated above room temperature, also sustaining gas phase presence of deposition precursors.

In some implementations, pedestals 2708 and 2710 support semiconductor or insulative wafers or substrates upon which films may be grown by impinging precursor molecules. The wafers or substrates may be heated to elevated temperatures to enable surface reactions, such as decomposition or polymerization of precursors to grow solid films on wafer surfaces. Spent process gases may flow past pedestals 2708 and 2710, and may be largely devoid of precursor molecules. A fraction of precursor molecules may be entrained within spent process gas flow bypassing pedestals 2708 and 2710.

Spent process gases may be collected at outlet ports 2712 and 2714 as process gas effluent, indicated by converging arrows at mouths of outlet ports 2712 and 2714. The process gas effluent may be exhausted from vacuum process chamber into interconnected conduits (e.g., conduits 2719, 2748 and 2750) of foreline network 2718. Arrows in conduit 2719 show flow of process gas effluent toward metering valve 2726. Process gas effluent passes through metering valve 2726 into expanded section 2724 of foreline outlet conduit 2722. In at least one implementation, valve 2736 in foreline outlet conduit 2722 is closed, directing effluent flow to enter bypass conduit 2728 at branch point 2730. Valve 2734 may be opened to enable flow into bypass conduit 2728. In some implementations, valves 2734 and 2736 are butterfly valves or gate valves. In at least one implementation, valves 2734 and 2736 may be coupled to actuators (not shown), that receive signals from a controller (not shown).

In at least one implementation, bypass conduit 2728 may be engineered to prevent sudden expansion of effluent gases flowing within, to mitigate condensation of entrained precursor vapors. A gradual pressure decrease may be developed by effluent flow within bypass conduit 2728, whereby dimensions of bypass conduit 2728 are optimized for a range of flow rates, as described above. Effluent gases may expand into lower section 2744 after more gradual expansion within portion 2742 of bypass conduit 2728. In at least one implementation, any entrained condensate (e.g., particulates) may be captured by filter 2738 as effluent flows through to exit vacuum pumping system 2720.

The bypass conduit 2728 may develop sufficient back pressure to maintain at least minimum working pressures within vacuum chamber 2702. In at least one implementation, working pressures may be 5 torr or greater. In at least one implementation, metering valve 2726 may be fully open during deposition processes since bypass conduit 2728 is operable to sustain working pressures in vacuum chamber 2702. Similar to described above, in at least one implementation, make-up or ballast gas (e.g., nitrogen, argon) may be introduced into the foreline, including the foreline network 2718, to boost pressure levels. The rate of flow of make-up gas may be adjusted by flow controller 3010. The make-up gas may be coupled into foreline network 2718 through conduit 3012 as described herein, such as via gas injectors not shown here and illustrated in FIGS. 1A-1C and 7A-8B, for example;. The working pressures within vacuum chamber 2702 may vary depending on a particular process.

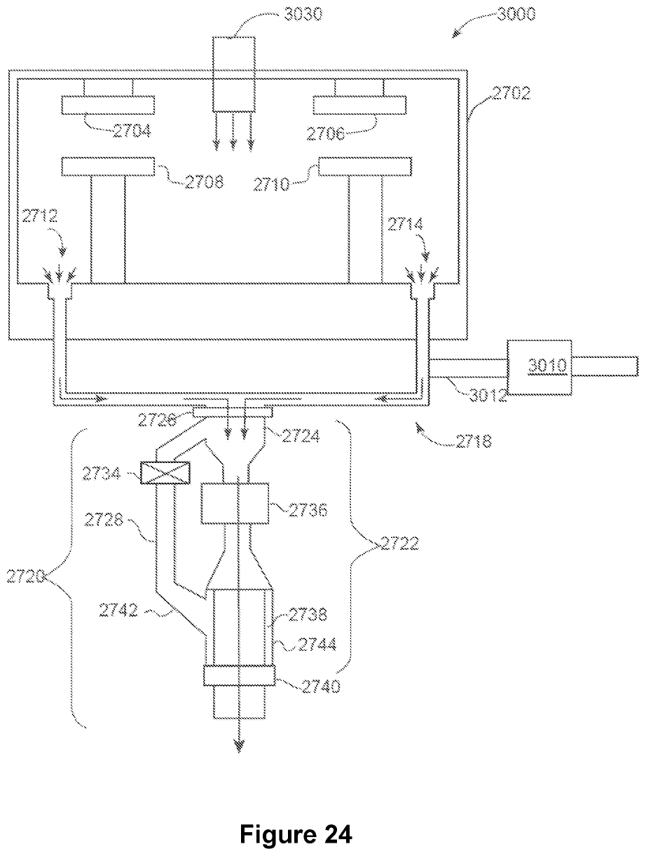

FIG. 24 depicts a cross-sectional view of process tool system 3000 undergoing a cleaning operation, according to at least one implementation. The cleaning gas may be introduced into vacuum chamber 2702 of process tool system 3000 through cleaning gas inlet port 3030. Down-pointing arrows below cleaning gas inlet port 3030 indicate introduction of cleaning gases into vacuum chamber 2702. Cleaning gases may comprise fluorinated compounds diluted in a carrier gas such as nitrogen or argon, and the cleaning gases may be preheated to elevated temperatures prior to entering cleaning gas inlet port 3030.

The cleaning gases may be collected at outlet ports 2712 and 2714 as cleaning gas effluent, indicated by converging arrows at mouths of outlet ports 2712 and 2714. In at least one implementation, cleaning gas effluent is exhausted from vacuum process chamber into interconnected conduits (e.g., conduits 2719, 2748 and 2750) of foreline network 2718. Arrows in conduit 2719 show flow of cleaning gas effluent toward metering valve 2726. The cleaning gas effluent passes through metering valve 127 into expanded section 2724 of foreline outlet conduit 2722. As shown here, valve 2736 in foreline outlet conduit 2722 is open, directing effluent flow to continue flowing down foreline outlet conduit 2722, as indicated by arrows. The valve 2734 may be closed to disable flow into bypass conduit 2728.

During cleaning operations, pressures within vacuum chamber 2702 may be reduced relative to working pressures of deposition processes. The pressures within vacuum chamber 2702 may be 1 torr or less and the cleaning gases may be swept rapidly through vacuum chamber 2702. The cleaning operations may employ higher flow rates at lower pressures than deposition operations. In some implementations, foreline outlet conduit 2722, has a greater diameter (e.g., D1, FIG. 20) than diameter of bypass conduit 2728 (e.g., D2, FIG. 20). Higher flow rates of cleaning gas may be supported by flowing cleaning gases through foreline outlet conduit 2722. Valve 2726 may be fully open during cleaning operations to enable large flow rates. In some implementations, valve 2726 may be omitted.

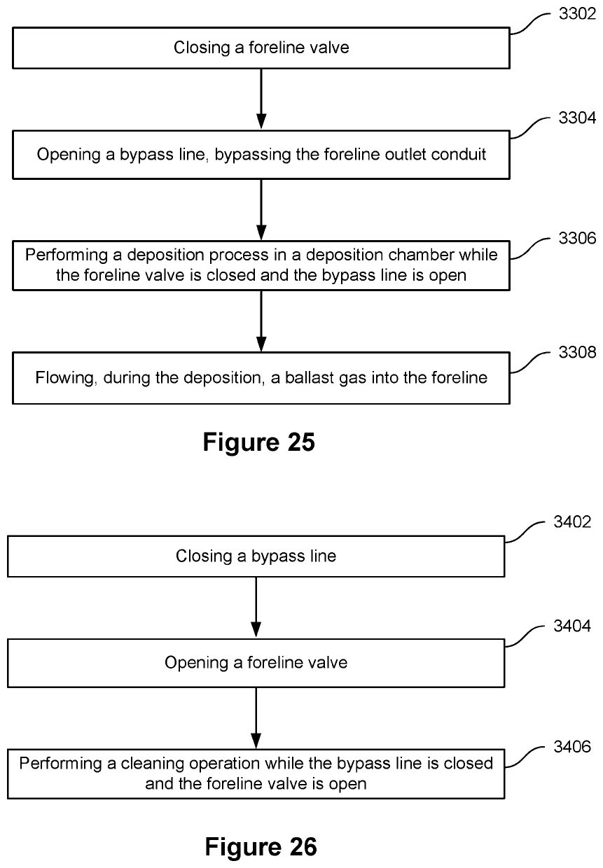

FIG. 25 depicts a flow chart of a technique for performing a deposition operation in a vacuum process chamber according to some implementations. Before or during the deposition process, the foreline valve, such as valve 2736 may be closed at operation 3302 and the bypass line may be opened at operation 3304. While the foreline valve is closed and bypass line is open, the deposition may be performed at operation 3306. During this deposition, the ballast gas may be flowed into the foreline at operation 3308, similar to described above.

At operation 3302, the, a valve in foreline (e.g., valve 2736) may be closed to direct effluent flow to bypass conduit 2728. For example, referring to FIG. 19, the spent process gases flowing through one or more process stations may flow into the outlet ports 2712 and 2714, and into the foreline network 2718. With valve 2736 closed, the gases flow to the bypass conduit 2728 which may provide a lower conductance path than the foreline outlet conduit 2722 to enable a gradual pressure drop (e.g., over length of bypass conduit) of effluent gases flowing toward vacuum pump. The gradual pressure drop of effluent gases can mitigate rapid expansion of effluent, preventing sudden condensation of precursor substances and deposition on interior surfaces of vacuum lines in vacuum system.

At operation 3304, the bypass conduit valve 2734 may be opened to enable effluent to flow through bypass conduit and rejoin foreline downstream of closed foreline valve 2736. The effluent reentering foreline may undergo some rapid expansion as volume of a lower section of foreline may be large relative to inner volume of bypass conduit. In at least one implementation, some condensate may be entrained by effluent reentering foreline. The grating or filter 2738 may be present within lower section of foreline to trap and filter out condensate and particulates entrained in effluent flow. The effluent may continue to flow to vacuum pumps at terminal end of vacuum system.

At operation 3306, at least one deposition process is performed in a vacuum chamber of a process tool (e.g., vacuum chamber 2702 of process tool 2700). The process tool may comprise multiple process stations as described above. During the deposition, one or more layers of a film may be grown on a substrate. The deposition process may be CVD, PECVD, or ALD, for example.

At operation 3308, the ballast gas may be introduced into the foreline network to provide a back pressure within the foreline network, allowing working pressure in the vacuum chamber to stay at a setpoint value. In at least one implementation, the bypass conduit (bypass conduit 2728), while a low conductance conduit, may not be able to sustain working pressures within the vacuum chamber at a desired precursor flow rate. The ballast gas may be introduced through a flow controller (e.g., flow controller 3010). The flow controller may dynamically control the flow rate of the ballast gas according to pressure fluctuations within the chamber. The ballast gas may comprise an inert gas such as argon or nitrogen. The flow controller may be adjusted to flow make-up gas from an external gas supply into the foreline network, boosting working pressures within the vacuum chamber.

FIG. 26 depicts a flow chart of a technique for performing a cleaning operation in a vacuum process chamber according to some implementations. At operation 3402 the bypass line may be closed and at operation 3404 the foreline outlet conduit may be opened. While the bypass line is closed and the foreline outlet conduit is opened, a cleaning operation may be performed at operation 3406. At operation 3402, referring to FIG. 19, the bypass conduit valve 2734 is closed to direct flow of cleaning gas effluent into higher conductance foreline outlet conduit 2722. At operation 3406, the foreline valve 2736 may be opened to direct flow into foreline outlet conduit 2722. In at least one implementation, the foreline outlet conduit 2722 has a greater diameter than the bypass conduit and provides a higher conductance flow path than the bypass conduit. In some instances, rapid expansion of cleaning gas effluent may not be a concern and the foreline outlet conduit 2722 may be preferred to conduct cleaning gas effluent as higher flow rates and lower chamber pressures may be supported.

At operation 3402, a cleaning process is performed in a vacuum chamber of a process tool (e.g., vacuum chamber 2702 of process tool 2700). The cleaning gases may comprise fluorine radicals and/or oxygen radicals. In at least one implementation, cleaning gases may be introduced into vacuum chamber by an inlet port (e.g., cleaning gas inlet port 3030). In at least one implementation, a cleaning operation may be performed at relatively low chamber pressures and higher flow rates than employed during deposition processes.

The following are additional implementations provided in view of the above-described implementations. Here, one or more features of an implementation, in isolation or in combination, can be combined with one or more features of one or more other implementations to form further implementations also falling within the scope of the disclosure. As such, various implementations can be combined with other implementations without changing the scope of the disclosure.

Implementation 1: An apparatus for a foreline anti-fouling assembly of a semiconductor processing system, the apparatus comprising: a catcher configured to be coupled to a foreline segment, the foreline segment configured to be fluidically connected with a foreline of the semiconductor processing system; wherein the catcher includes an accumulation surface configured to be impinged upon by a flow of a process gas through the foreline segment and cause material from the process gas to be deposited on the accumulation surface during a semiconductor processing operation when the catcher is coupled to the foreline segment and the foreline segment is fluidically connected with the foreline; and wherein the accumulation surface are further configured to be impinged upon by plasma to remove the material from the accumulation surface during a foreline cleaning operation when the catcher is coupled to the foreline segment and the foreline segment is fluidically connected with the foreline.

Implementation 2: The apparatus of implementation 1, wherein the catcher comprises a conduit including a first end portion, with the first end portion being an open end having a rim defining an inlet; the inlet is configured to receive the flow of the process gas during the semiconductor processing operation; and the inlet is further configured to receive the flow of plasma during the foreline cleaning operation.

Implementation 3. The apparatus of implementation 2, wherein the conduit further includes a second end portion opposite to the first end portion; the accumulation surface comprises a first accumulation surface spaced from the second end portion and a second accumulation surface on the second end portion; and the second end portion is configured to catch the material dislodged from the first accumulation surface.

Implementation 4: The apparatus of implementation 3, wherein the conduit is made of a steel alloy, an aluminum alloy, or a ceramic material.

Implementation 5: The apparatus of implementation 3, wherein the second end portion of the conduit is a closed end.

Implementation 6: The apparatus of implementation 5, further comprising a support structure configured to attach the first end portion of the conduit to the foreline segment.

Implementation 7: The apparatus of implementation 6, wherein the second end portion of the conduit is free of the support structure.

Implementation 8: The apparatus of implementation 3, wherein the conduit includes a lateral wall extending between the first end portion and the second end portion and defining a passage along a longitudinal axis, the lateral wall being configured to retain the material deposited from the process gas within the passage of the catcher.

Implementation 9: The apparatus of implementation 8, wherein the lateral wall includes an outlet, and the passage is fluidically interposed between the inlet and the outlet.

Implementation 10: The apparatus of implementation 9, wherein the outlet in the lateral wall is spaced from the second accumulation surface, and the lateral wall includes an annular flange configured to retain the material within the passage of the catcher.

Implementation 11: The apparatus of implementation 3, wherein the conduit includes a column extending between the first end portion and the second end portion, the column being configured to retain the material within a passage of the catcher.

Implementation 12: The apparatus of implementation 1, wherein the accumulation surface comprises a direct impingement section extending in a direction having a lateral component perpendicular to a longitudinal axis of the catcher; for each location in a first set of locations, multiple direct lines of sight exist from that location to corresponding viewpoints external to the catcher and located along an upstream direction of the foreline relative to the catcher; each location in the first set of locations is located on the direct impingement section; the direct impingement section comprises a lateral occlusion profile in the foreline; and the lateral occlusion profile is configured to occlude a range between 10% and 90% of a segment cross-sectional area of the foreline segment.

Implementation 13: The apparatus of implementation 1, wherein the catcher comprises a plurality of panels having the accumulation surface.

Implementation 14: The apparatus of implementation 1, wherein the accumulation surface includes a planar surface portion, a convex surface portion, or a concave surface portion.

Implementation 15: The apparatus of implementation 1, wherein the catcher comprises a post having a shaft terminating at a tip, with one or both of the shaft and the tip including the accumulation surface.

Implementation 16: A semiconductor processing system comprising a processing chamber defining an interior volume; a foreline fluidically connected with the interior volume of the processing chamber and configured to receive a flow of a process gas from the processing chamber, the foreline having an exhaust interface configured to connect with an exhaust system; a valve in the foreline and including an orifice; and a catcher in the foreline and configured to be fluidically interposed between the valve and the exhaust interface of the foreline; wherein the catcher includes an accumulation surface configured to be impinged upon by a flow of a process gas through the foreline and cause material from the process gas to be deposited on the accumulation surface during a semiconductor processing operation when the catcher is coupled to the foreline; and wherein the accumulation surface are further configured to be impinged upon by plasma to remove the material from the accumulation surface during a foreline cleaning operation when the catcher is coupled to the foreline.

Implementation 17: The semiconductor processing system of implementation 16, wherein the valve comprises a sealing ring coaxially positioned with the foreline; and a gate having an outer edge region, wherein the gate is movable between a first position where the outer edge region sealingly engages with at least a portion of the sealing ring and a second position where a portion of the outer edge region is displaced radially inward from an interior perimeter of the sealing ring.

Implementation 18: The semiconductor processing system of implementation 17, wherein the orifice is located in a region of the gate that lies within a center region of the sealing ring when the gate is in the first position.

Implementation 19: The semiconductor processing system of implementation 18, wherein the catcher comprises a post having a shaft terminating at a tip, one or both of the shaft and the tip including the accumulation surface and the shaft being positioned coaxially with the orifice in the gate.

Implementation 20: The semiconductor processing system of implementation 17, wherein: the catcher comprises a conduit including a first end portion, the first end portion being an open end having a rim defining an inlet; the inlet is configured to receive the flow of the process gas during the semiconductor processing operation; and the inlet is further configured to receive the flow of plasma during the foreline cleaning operation.

Implementation 21: The semiconductor processing system of implementation 20, wherein the inlet in the catcher and the orifice in the gate are positioned coaxially when the gate is in the first position.

Implementation 22: The semiconductor processing system of implementation 20, wherein the orifice in the gate has a first diameter, and the inlet of the catcher has a second diameter that is larger than the first diameter of the orifice in the gate.

Implementation 23: The semiconductor processing system of implementation 22, wherein a ratio of the second diameter of the inlet to the first diameter of the orifice is at least 1.5:1.

Implementation 24: The semiconductor processing system of implementation 20, wherein the conduit further includes a second end portion opposite to the first end portion; the accumulation surface includes a first accumulation surface spaced from the second end portion and a second accumulation surface on the second end portion; and the second end portion is configured to catch the material that is dislodged from the first accumulation surface.

Implementation 25: The semiconductor processing system of implementation 24, wherein the conduit is made of a steel alloy, an aluminum alloy, or a ceramic material.

Implementation 26: The semiconductor processing system of implementation 24, wherein the second end portion of the conduit is a closed end.

Implementation 27: The semiconductor processing system of implementation 26, further comprising a support structure configured to attach the first end portion of the conduit to the foreline.

Implementation 28: The semiconductor processing system of implementation 27, wherein the second end portion of the conduit is free of the support structure.

Implementation 29: The semiconductor processing system of implementation 24, wherein the conduit includes a lateral wall extending between the first end portion and the second end portion and defining a passage along a longitudinal axis, with the lateral wall being configured to retain the material deposited from the process gas within the passage of the catcher.

Implementation 30: The semiconductor processing system of implementation 29, wherein the lateral wall includes an outlet, and the passage is fluidically interposed between the inlet and the outlet.

Implementation 31: The semiconductor processing system of implementation 30, wherein the outlet comprises a single outlet or a set of outlets at one or more angular positions of the lateral wall.

Implementation 32: The semiconductor processing system of implementation 16, wherein the accumulation surface comprises a direct impingement section extending in a direction having a lateral component perpendicular to a longitudinal axis of the catcher; for each location in a first set of locations, multiple direct lines of sight exist from that location to corresponding viewpoints external to the catcher and located along an upstream direction of the foreline relative to the catcher; each location in the first set of locations is located on the direct impingement section; and the direct impingement section comprises a lateral occlusion profile in the foreline, wherein the lateral occlusion profile is configured to occlude a range between 10% and 50% of a segment cross-sectional area of the foreline.

Implementation 33: The semiconductor processing system of implementation 16, wherein the catcher is coupled to a foreline segment of the foreline; and the foreline segment is an integral portion of the foreline or a separate flanged tube fluidically interposed between a first portion of the foreline and a second portion of the foreline.

Implementation 34: The semiconductor processing system of implementation 33, wherein the separate flanged tube includes an inlet end configured to fluidically connect with the first portion of the foreline fluidically connected with the interior volume of the processing chamber, an outlet end configured to fluidically connect with the second portion of the foreline fluidically connected with the exhaust system, and a flow path fluidically interposed between the inlet end and the outlet end.

Implementation 35: The semiconductor processing system of implementation 34, wherein the flow path of the foreline segment without the catcher in the foreline segment has a segment cross-sectional area; and the catcher comprises a lateral occlusion profile configured to occlude a range between 10% and 50% of the segment cross-sectional area of the foreline segment when the catcher without the material deposited on the catcher is installed within the flow path of the foreline segment.

Implementation 36: The semiconductor processing system of implementation 35, wherein the accumulation surface comprises a direct impingement section extending in a second direction having a lateral component that is perpendicular to a longitudinal axis of the catcher; and the lateral occlusion profile comprises an aggregate cross-sectional area of the lateral components of all of the direct impingement section.

Implementation 37: A semiconductor processing system comprising a processing chamber defining an interior volume; and a foreline fluidically connected with the interior volume of the processing chamber and configured to receive a flow of a process gas from the processing chamber, the foreline having an exhaust interface configured to connect with an exhaust system; wherein the foreline further includes a remote plasma source interface (RPS interface) fluidically interposed between the interior volume of the processing chamber and the exhaust interface; and wherein the RPS interface is configured to fluidically connect with a remote plasma source and direct plasma flow from the remote plasma source into the foreline without first flowing through the interior volume of the processing chamber.

Implementation 38: The semiconductor processing system of implementation 37, wherein the RPS interface is fluidically interposed between the interior volume of the processing chamber and a focus region of the foreline, wherein material is deposited at the focus region at a rate higher than a first threshold rate at which material is deposited on another focus region of the foreline during a semiconductor processing operation conducted in the interior volume.

Implementation 39: The semiconductor processing system of implementation 37 or implementation 38, wherein the foreline branches into multiple segments defining a plurality of flow paths, each flow path leading to a different exhaust port of the processing chamber, the segments including a non-linear section that each define a non-linear portion of the corresponding flow path through the foreline; and the RPS interface is fluidically interposed between at least one of the non-linear portions of the corresponding flow paths and the exhaust interface.

Implementation 40: The semiconductor processing system of implementation 39, wherein the RPS interface is fluidically interposed between all of the non-linear portions of the flow paths and the exhaust interface.

Implementation 41: The semiconductor processing system of any of implementations 37 to 40, wherein the RPS interface defines a plasma passage configured to direct the plasma flow, during a foreline cleaning process, along a direction having a component that parallels a downstream direction of the foreline.

Implementation 42: The semiconductor processing system of implementation 41, wherein the foreline includes a foreline wall, and the plasma passage is configured to direct the plasma flow, during the foreline cleaning process, along a direction that is at between 30 degrees and 60 degrees relative to the foreline wall.

Implementation 43: The semiconductor processing system of implementation 37, wherein the RPS interface includes a nozzle having a plasma passage fluidically interposed between the remote plasma source and the RPS interface of the foreline.

Implementation 44: The semiconductor processing system of implementation 43, wherein the RPS interface includes a nozzle having a first end portion connected with the remote plasma source and a second end portion connected with the RPS interface of the foreline; and the plasma passage includes a first segment with a first diameter in the first end portion of the nozzle and a second segment with a second diameter in the second end portion of the nozzle, and the first diameter of the first segment is larger than the second diameter of the second segment.

Implementation 45: The semiconductor processing system of implementation 43, wherein the nozzle has a nozzle wall including a surface defining the plasma passage; the nozzle wall has a first end portion connected with the remote plasma source and a second end portion connected with the RPS interface of the foreline; and the nozzle includes an inlet port and an outlet port both located in the first end portion of the nozzle wall; and a coolant passage located in the nozzle wall, the coolant passage defining a flow path leading from the inlet port to the outlet port and passing through the second end portion.

Implementation 46: The semiconductor processing system of implementation 45, wherein the coolant passage comprise a serpentine coolant passage alternately passing through multiple sections of the first end portion and multiple sections of the second end portion, the serpentine coolant passage having one end fluidically connected with the inlet port and another end fluidically connected with the outlet port.

Implementation 47: The semiconductor processing system of implementation 43, wherein the RPS interface comprises a nozzle having a first end portion connected with the remote plasma source and a second end portion connected with the RPS interface of the foreline, and the nozzle has a nozzle wall including a first surface facing radially inward toward and defining the plasma passage along a central axis, the nozzle wall further including a second surface facing radially outward relative to the central axis; and one or more heat sinks attached to the second surface, wherein the one or more heat sinks each having one or more coolant passages fluidically interposed between an inlet port and an outlet port.

Implementation 48: The semiconductor processing system of implementation 47, wherein the one or more heat sinks comprises a first block and a second block clamped to the nozzle by one or more fasteners.

Implementation 49: The semiconductor processing system of implementation 48, wherein the first block and the second block are made of aluminum, copper, or nickel.

Implementation 50: The semiconductor processing system of implementation 48, wherein a connector line is fluidically interposed between the one or more coolant passages of the first block and the one or more coolant passages of the second block.

Implementation 51: The semiconductor processing system of implementation 47, wherein the one or more coolant passages are located external to at least one of the foreline and the nozzle.

Implementation 52: The semiconductor processing system of implementation 51, wherein the one or more heat sinks are attached to the first end portion of the nozzle adjacent to the remote plasma source.

Implementation 53: The semiconductor processing system of implementation 43, wherein the nozzle protrudes into an interior of the foreline.

Implementation 54: The semiconductor processing system of implementation 37, wherein the RPS interface terminates in an opening defined in a foreline wall of the foreline.

Implementation 55: The semiconductor processing system of implementation 37, wherein the foreline includes a pendulum valve fluidically interposed between the RPS interface and the exhaust interface.

Implementation 56: The semiconductor processing system of implementation 55, wherein the pendulum valve comprises a sealing ring coaxially positioned with the foreline; and a gate having an outer edge region, wherein the gate is movable between a first position where the outer edge region sealingly engages with at least a portion of the sealing ring and a second position where a portion of the outer edge region is displaced radially inward from an interior perimeter of the sealing ring.

Implementation 57: The semiconductor processing system of implementation 56, wherein the RPS interface defines a plasma passage configured to direct the plasma flow towards a location where the outer edge region of the gate is when the gate is in the second position.

Implementation 58: The semiconductor processing system of implementation 57, wherein the gate includes an orifice located in a region of the gate that lies within a center region of the sealing ring when the gate is in the first position.

Implementation 59: The semiconductor processing system of implementation 58, further comprising a gas distribution system including a plurality of valves controllable to selectively cause the process gas from a plurality of different gas sources connectable to the gas distribution system to be flowed into the processing chamber; and a controller, wherein the controller is configured to control the valves of the gas distribution system to cause the process gas to be flowed into the processing chamber during a semiconductor processing operation to adjust a chamber pressure when the gate is in the first position where the outer edge region of the gate sealingly engages with at least a portion of the sealing ring and blocks a flow of the process gas through an interface between the outer edge region and the sealing ring.

Implementation 60: The semiconductor processing system of implementation 59, wherein the controller is configured to control the valves of the gas distribution system to not cause the process gas to be flowed into the processing chamber during a foreline cleaning process.

Implementation 61: The semiconductor processing system of implementation 60, wherein the remote plasma source is configured to produce plasma with at least one of oxygen and fluorine.

Implementation 62: The semiconductor processing system of implementation 60, further comprising the remote plasma source and a foreline plasma valve fluidically interposed between the remote plasma source and the RPS interface of the foreline, wherein the controller is configured to control the remote plasma source and the foreline plasma valve to cause plasma from the remote plasma source to be flowed into the foreline during the foreline cleaning process.

Implementation 63: The semiconductor processing system of implementation 62, wherein the controller is configured to control the foreline plasma valve to block the process gas from flowing through the RPS interface and preventing material from being deposited in the RPS interface during the semiconductor processing operation.

Implementation 64: The semiconductor processing system of implementation 58, wherein the portion of the outer edge region includes a notch configured to flow a portion of the process gas when the gate is moved by a small angular movement below a predetermined angle from the first position toward the second position and permit the pendulum valve to precisely control and gradually adjust a flow rate of the process gas; and a flow of the process gas is distributed between the orifice and the notch when the gate is in the second position where the gate is positioned radially inward from the interior perimeter of the sealing ring.

Implementation 65: The semiconductor processing system of implementation 64, further comprising a gate valve fluidically interposed between the RPS interface and the pendulum valve, wherein the gate valve is configured to move between an open position and a closed position where the gate valve completely blocks all of the process gas from flowing through the foreline.

Implementation 66: The semiconductor processing system of implementation 37, wherein the RPS interface is made of anodized aluminum alloy.

Implementation 67: The semiconductor processing system of implementation 37, wherein the remote plasma source is separate from a chamber cleaning plasma source and configured to supply plasma to the processing chamber.

Implementation 68 is a process tool which comprises: a vacuum chamber; a first conduit having a first diameter, wherein the first conduit is coupled to the vacuum chamber via a foreline network, and wherein the foreline network is coupled to an outlet on the vacuum chamber; and a second conduit coupled to the first conduit, wherein the second conduit has a second diameter less than the first diameter.

Implementation 69 is the process tool of any implementation herein, particularly implementation 68, wherein the second conduit branches from the first conduit at a branch point located at a first distance from a junction of the first conduit and the foreline network, and rejoins the first conduit at a reentry point located at a second distance from the junction of the first conduit and the foreline network, wherein the second distance is greater than the first distance.

Implementation 70 is the process tool of any implementation herein, particularly implementation 69, wherein a first valve is situated on the first conduit between the branch point and the reentry point, and wherein a second valve is situated between the foreline network and the first conduit.

Implementation 71 is the process tool of any implementation herein, particularly implementation 70, wherein the first valve and the second valve are any of a ball valve, a butterfly valve, or a gate valve.

Implementation 72 is the process tool of any implementation herein, particularly implementation 70, wherein a third valve is situated between the foreline network and the first conduit.

Implementation 73 is the process tool of any implementation herein, particularly implementation 69, wherein the third valve is a pendulum valve, a butterfly valve, or a gate valve.

Implementation 74 is the process tool of any implementation herein, particularly implementation 73, wherein a filter is situated within the first conduit adjacent to the reentry point.

Implementation 75 is the process tool of any implementation herein, particularly implementation 74, wherein the filter comprises a plurality of openings, wherein the plurality of openings has at least one characteristic diameter.

Implementation 76 is the process tool of any implementation herein, particularly implementation 75, wherein the at least one characteristic diameter is 3 mm or less.

Implementation 77 is the process tool of any implementation herein, particularly any one of implementations 68-76, wherein the foreline network comprises a third conduit coupled to the outlet of the vacuum chamber and the first conduit.

Implementation 78 is the process tool of any implementation herein, particularly implementation 77, further comprising at least one fourth conduit coupled to the foreline network.

Implementation 79 is a process tool system, comprising: a process chamber; a first conduit having a first diameter coupled to the process chamber via an foreline network, wherein the first conduit is coupled to the foreline network, and wherein the foreline network is coupled to one or more outlets on the process chamber; a second conduit coupled to the first conduit, wherein the second conduit has a second diameter less than the first diameter, wherein the process tool system comprises a vacuum pump coupled to the first conduit; and a flow controller coupled to the foreline network.

Implementation 80 is the process tool system of any implementation herein, particularly implementation 79, wherein the foreline network comprises a plurality of interconnected third conduits, wherein the plurality of interconnected third conduits is coupled to the one or more outlets on the process chamber and the first conduit.

Implementation 81 is the process tool system of any implementation herein, particularly implementation 79, further comprising a fourth conduit coupled to the foreline network, wherein the flow controller is coupled to the fourth conduit.

Implementation 82 is the process tool system of any implementation herein, particularly implementation 81, wherein a gas supply is coupled to the flow controller.

Implementation 83 is the process tool system of any implementation herein, particularly implementation 79, wherein a first valve is situated on the first conduit, and wherein a second valve is situated on the second conduit.

Implementation 84 is the process tool system of any implementation herein, particularly implementation 83, wherein the first valve is coupled to a first valve actuator, and the second valve is coupled to a second valve actuator.

Implementation 85 is a method comprising performing a deposition process in a deposition process tool, wherein the deposition process tool comprises: a process chamber; a first conduit having a first diameter, wherein the first conduit is coupled to the process chamber via an foreline network, and wherein the foreline network is coupled to an outlet on the process chamber; and a second conduit coupled to the first conduit, wherein the second conduit has a second diameter less than the first diameter, wherein the second conduit has a lower flow conductance for a process gas relative to the first conduit; closing a first valve on the first conduit to block a flow of the process gas through the first conduit; and opening a second valve on the second conduit, wherein the process gas flows through the second conduit, and wherein the flow of the process gas through the second conduit is limited by the second diameter

Implementation 86 is the method of any implementation herein, particularly implementation 85, further comprising flowing a ballast gas into the foreline network.

Implementation 87 is the method of any implementation herein, particularly implementation 86, wherein flowing the ballast gas into the foreline network comprises adjusting a flow rate of the ballast gas to maintain a minimum pressure within the process chamber.

Implementation 88 is a method comprising flowing a cleaning gas into a process tool, wherein the process tool comprises: a process chamber; and a process gas exhaust system coupled to the process chamber, wherein the process gas exhaust system comprises: a first conduit coupled to the process chamber via an foreline network, and wherein the foreline network is coupled to an outlet on the process chamber; and a second conduit coupled to the first conduit; and opening a first valve on the first conduit, wherein a flow of the cleaning gas exits the foreline network and flows through the first conduit.

Implementation 89 is the method of any implementation herein, particularly implementation 88, further comprising closing a second valve in the second conduit, wherein the second conduit is bypassed by the flow of the cleaning gas.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system, with process gases flowing from the processing chamber 106 and through the foreline 102 where material from the flow of process gases is deposited. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. For purposes of clarity, the same reference numbers will be used in the drawings to identify similar elements. As used herein, the phrase at least one of A, B, and C should be construed to mean a logical (A, B, or C), using a non-exclusive logical OR. It should be understood that one or more steps within a method may be executed in different order (or concurrently) without altering the principles of the present disclosure.

1. A semiconductor processing system comprising:
a processing chamber defining an interior volume;
a foreline fluidically connected to the interior volume and configured to receive process gases from the interior volume, wherein the foreline has a foreline network and a foreline outlet conduit downstream of the foreline network;
a throttle valve in the foreline outlet conduit, having a movable gate with an orifice, and configured to control a flow of gases through the foreline; and
a gas injector in the foreline network and configured to direct a ballast gas into a conduit of the foreline network.

2. The system of claim 1, wherein the gas injector has an outlet positioned in the center of the conduit.

3. The system of claim wherein the gas injector has an outlet with a circular cross-sectional area.

4. The system of claim 3, wherein the conduit has an internal bore diameter between about two times and about six times the diameter of the outlet.

5. (canceled)

6. The system of claim 1, wherein:
the foreline network includes:
a first segment spanning between a first exhaust port of the processing chamber and a junction,
a second segment spanning between a second exhaust port of the processing chamber and the junction, and
a third segment spanning between, and fluidically interposed between, the junction and the foreline, and
the conduit is a part of the third segment such that the gas injector is positioned along the third segment and configured to direct the ballast gas flow into the third segment.

7. The system of claim 1, further comprising a catcher in the foreline outlet conduit and downstream of the movable gate, wherein gas flowing through the foreline is configured to contact the catcher.

8. The system of claim 7, wherein the catcher comprises an accumulation surface configured to be impinged upon by the gas flowing through the foreline.

9. The system of claim 7, wherein when the throttle valve is in a closed position, gas is configured to flow through the orifice and into the catcher.

10. The system of claim 7, wherein the catcher further comprises an inlet configured to receive the gas and a plurality of outlets.

11. (canceled)

12. The system of claim 1, wherein a surface of the movable gate comprises an aluminum.

13. (canceled)

14. The system of claim 1, further comprising a remote plasma source interface (RPS interface) fluidically connected to the foreline outlet conduit, downstream of the interior volume, and having a plasma passage configured to direct a remote plasma flow into the foreline outlet conduit.

15. The system of claim 14, wherein the RPS interface is fluidically interposed between the foreline network and the throttle valve.

16. The system of claim 14, wherein the plasma passage is configured to direct the plasma flow along a direction having a component parallel to a center axis of the foreline outlet conduit.

17. (canceled)

18. The system of claim 14, wherein the plasma passage is configured to direct the plasma flow along a direction having a component perpendicular to a center axis of the foreline outlet conduit.

19. The system of claim 14, wherein the RPS interface further comprises a nozzle defining the plasma passage and extending into an interior of the foreline outlet conduit.

20. The system of claim 14, wherein:
the plasma passage has a first end portion and a second end portion configured to direct the plasma flow into the foreline outlet conduit,
the first end portion has a first diameter, and
the second end portion has a second diameter smaller than the first diameter.

21. (canceled)

22. (canceled)

23. The system of claim 1, further comprising:
a ballast gas source fluidically connected to the gas injector; and
one or more controllers having one or more processors and one or more memories that store instructions for controlling the system, the instructions are configured to cause the one or more processors to cause ballast gas to flow through the gas injector and into the foreline network during one or more processing operations.

24. The system of claim 23, further comprising a pressure sensor configured to detect a pressure upstream of the gas injector, wherein the instructions are further configured to cause the one or more processors to cause:
one controller to receive signals from the pressure sensor, and
the ballast gas to flow, based on a detected pressure, through the gas injector and thereby maintain a portion of the foreline network within a pressure range.

25-30. (canceled)

31. The system of claim 24, wherein the instructions are further configured to cause the one or more processors to cause the throttle valve to control the pressure within the interior volume during one or more other operations that are not the one or more processing operations.

32. (canceled)

33. The system of claim 31, further comprising:
a remote plasma source (RPS) configured to generate a remote plasma; and
a remote plasma source interface (RPS interface) fluidically connected to the foreline and the RPS, downstream of the interior volume, and having a plasma passage configured to direct the remote plasma flow from the RPS into the foreline outlet conduit, wherein the instructions are further configured to cause the one or more processors to cause:
the RPS to generate the remote plasma, and
the remote plasma to flow into the foreline outlet conduit during the cleaning operation.

34-43. (canceled)
